(19) United States
(12) Patent Application Publication
(10) Pub. No.: US 2026/0040675 A1
(43) Pub. Date: Feb. 5, 2026

(54) MONOLITHIC STACKED COMPLEMENTARY TRANSISTOR STRUCTURES WITH DUAL WORK FUNCTION METAL GATES

(71) Applicant: International Business Machines Corporation, Armonk, NY (US)

(72) Inventors: Shay Reboh, Guilderland, NY (US); Shahrukh Khan, Sandy Hook, CT (US); Takashi Ando, Eastchester, NY (US); Jay William Strane, Wappingers Falls, NY (US)

(21) Appl. No.: 18/791,720

(22) Filed: Aug. 1, 2024

(51) Int. Cl. H01L 27/092; H01L 21/28; H01L 21/822; H01L 21/8238; H01L 29/06; H01L 29/423; H01L 29/49; H01L 29/66; H01L 29/775; H01L 29/786

(52) U.S. Cl. CPC H10D 84/856; H01L 21/28088; H10D 30/014; H10D 30/43; H10D 30/6735; H10D 30/6739; H10D 30/6757; H10D 62/121; H10D 64/017; H10D 84/0177; H10D 84/038; H10D 88/01

(57) ABSTRACT

A device comprises a stacked transistor structure and a shared gate structure. The stacked transistor structure comprises a first transistor of a first type, and a second transistor of a second type which is opposite the first type, and which is disposed over the first transistor. The shared gate structure comprises a first metal gate structure of the first transistor, a second metal gate structure of the second transistor, and a metallic connection layer. The second metal gate structure is embedded in the first metal gate structure with a dielectric layer disposed between the first metal gate structure and the second metal gate structure. The metallic connection layer electrically connects upper regions of the first metal gate structure and the second metal gate structure.

### BACKGROUND

This disclosure relates generally to monolithic three-dimensional (3D) integration techniques and, in particular, techniques for fabricating monolithic 3D semiconductor integrated circuit devices comprising stacked complementary metal-oxide semiconductor (CMOS) transistor structures. Continued innovations in semiconductor process technologies are enabling higher integration densities and device scaling. In particular, state-of-the-art 3D integration technologies are poised to become critical technology boosters for providing extremely dense integrated circuits. A 3D monolithic design comprises stacked layers of field-effect transistor (FET) devices to reduce a device footprint. For example, a FET-over-FET integration scheme is one form of a 3D monolithic integration scheme in which p-type FET (PFET) and n-type FET (NFET) devices are formed in different device layers on a single substrate. While stacked CMOS structures allow for increased transistor density by stacking PFET devices and NFET devices on top of each other, the ability to form dual work function metal gate layers to optimize device performance of the stacked P-type and N-type FET devices is not trivial.

### SUMMARY

Exemplary embodiments of the disclosure include semiconductor integrated circuit devices comprising stacked transistor structures (e.g., stacked complementary transistor structures) with dual work function metal gates, and methods for fabricating such semiconductor integrated circuit devices.

For example, an exemplary embodiment includes a device which comprises a stacked transistor structure and a shared gate structure. The stacked transistor structure comprises a first transistor of a first type, and a second transistor of a second type which is opposite the first type, and disposed over the first transistor. The shared gate structure comprises a first metal gate structure of the first transistor, a second metal gate structure of the second transistor, and a metallic connection layer. The second metal gate structure is embedded in the first metal gate structure with a dielectric layer disposed between the first metal gate structure and the second metal gate structure. The metallic connection layer electrically connects upper regions of the first metal gate structure and the second metal gate structure.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a first metal gate structure of the first transistor, and a second metal gate structure of the second transistor. The second metal gate structure is embedded in the first metal gate structure with a dielectric layer disposed between the first metal gate structure and the second metal gate structure.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a dielectric isolation layer, a first metal gate structure of the first transistor, and a second metal gate structure of the second transistor. The second metal gate structure is embedded in the dielectric isolation layer with a dielectric layer comprised of gate dielectric material disposed between the second metal gate structure and the dielectric isolation layer. The first metal gate structure is disposed below the dielectric isolation layer.

Another exemplary embodiment includes a device which comprises a first stacked transistor structure and a second stacked transistor structure disposed on a substrate. The first stacked transistor structure comprises a first transistor of a first type, a second transistor of a second type which is opposite the first type, and disposed over the first transistor, and a first split gate structure. The first split gate structure comprises a first metal gate structure of the first transistor, and a second metal gate structure of the second transistor, wherein the first metal gate structure and the second metal gate structure are isolated from each other. The second stacked transistor structure comprises a third transistor of the second type, a fourth transistor of the first type and disposed over the third transistor, and a second split gate structure. The second split gate structure comprises a third metal gate structure of the third transistor, and a fourth metal gate structure of the fourth transistor, wherein the third metal gate structure and the fourth metal gate structure are isolated from each other. A first metallic connection element connects the second metal gate structure and the fourth metal gate structure.

Another exemplary embodiment includes a method for fabricating a semiconductor integrated circuit device. The method comprises forming a stacked transistor structure which comprises a first transistor of a first type, a second transistor of a second type, which is opposite the first type and disposed over the first transistor, and forming a gate structure which comprises a first metal gate structure of the first transistor, and a second metal gate structure of the second transistor, wherein the second metal gate structure is embedded in the first metal gate structure with a dielectric layer disposed between the first metal gate structure and the second metal gate structure.

Other embodiments will be described in the following detailed description of embodiments, which is to be read in conjunction with the accompanying figures.

### BRIEF DESCRIPTION OF THE DRAWINGS

FIGS. 1A and 1B are schematic views of a semiconductor integrated circuit device comprising a stacked complementary transistor structure, according to an exemplary embodiment of the disclosure.

FIG. 2 is a schematic cross-sectional side view of a semiconductor integrated circuit device comprising a stacked complementary transistor structure, according to another exemplary embodiment of the disclosure.

FIG. 3 is schematic cross-sectional side view of a semiconductor integrated circuit device comprising a stacked complementary transistor structure, according to another exemplary embodiment of the disclosure.

FIG. 4 is a schematic cross-sectional side view of a semiconductor integrated circuit device comprising a stacked complementary transistor structure, according to another exemplary embodiment of the disclosure.

FIG. 5 is a schematic cross-sectional side view of a semiconductor integrated circuit device comprising a pair of stacked complementary transistor structures which enable a cross-coupled gate configuration, according to an exemplary embodiment of the disclosure.

FIG. 6 is a schematic cross-sectional side view of a semiconductor integrated circuit device comprising a pair of stacked complementary transistor structures which enable a cross-coupled gate configuration, according to another exemplary embodiment of the disclosure.

FIGS. 7A and 7B schematically illustrate stacked complementary transistor structures with cross-coupled gate configurations, according to another exemplary embodiment of the disclosure.

FIGS. 8A-8M schematically illustrate a method for fabricating a semiconductor integrated circuit device comprising a stacked complementary transistor structure, according to an exemplary embodiment of the disclosure, wherein:

FIG. 8A is a schematic cross-sectional side view of an intermediate structure of the semiconductor integrated circuit device which comprises a dummy gate that is to be replaced with a metal gate;

FIG. 8B is a schematic cross-sectional side view of an intermediate structure of the semiconductor integrated circuit device which is obtained after forming a trench opening in the dummy gate to expose a second (upper) stack of epitaxial semiconductor layers of a patterned stack of epitaxial semiconductor layers;

FIG. 8C is a schematic cross-sectional side view of an intermediate structure of the semiconductor integrated circuit device which is obtained after filling the trench opening with sacrificial dielectric material;

FIG. 8D is a schematic cross-sectional side view of an intermediate structure of the semiconductor integrated circuit device which is obtained after removing a remaining portion of the dummy gate to form an open region that exposes the underlying first stack of epitaxial semiconductor layers;

FIG. 8E is a schematic cross-sectional side view of an intermediate structure of the semiconductor integrated circuit device which is obtained after selectively etching sacrificial layers of the first stack of epitaxial semiconductor layers to release nanosheet channel layers of a first transistor;

FIG. 8F is a schematic cross-sectional side view of an intermediate structure of the semiconductor integrated circuit device which is obtained after forming high-k gate dielectric layers on exposed surfaces of the nanosheet channel layers of the first transistor 110;

FIG. 8G is a schematic cross-sectional side view of an intermediate structure of the semiconductor integrated circuit device which is obtained after forming a first metal gate electrode of the first transistor;

FIG. 8H is a schematic cross-sectional side view of an intermediate structure of the semiconductor integrated circuit device which is obtained after removing the sacrificial dielectric material to form a trench opening which exposes the second stack of epitaxial semiconductor layers;

FIG. 8I is a schematic cross-sectional side view of an intermediate structure of the semiconductor integrated circuit device which is obtained after selectively etching away sacrificial layers of the second stack of epitaxial semiconductor layers to release nanosheet channel layers of a second transistor;

FIG. 8J is a schematic cross-sectional side view of an intermediate structure of the semiconductor integrated circuit device which is obtained after forming interfacial layers and high-k gate dielectric layers on exposed surfaces of the nanosheet channel layers of the second transistor;

FIG. 8K is a schematic cross-sectional side view of an intermediate structure of the semiconductor integrated circuit device which is obtained after forming a second metal gate electrode of the second transistor; and

FIG. 8L is a schematic cross-sectional side view of an intermediate structure of the semiconductor integrated circuit device which is obtained after recessing the first metal gate electrode and the second metal gate electrode to form a recessed cavity in which metal is deposited to form a metallic strap to connect the first and second metal gate electrodes.

FIG. 8M illustrates an alternative embodiment of a process flow which, starting with the intermediate structure of the semiconductor integrated circuit device of FIG. 8K, comprises patterning an open trench in portions of the first metal gate electrode and the second metal gate electrode in which metal is deposited to form a metallic plug connecting the first and second metal gate electrodes.

FIGS. 9A-9G schematically illustrate a method for fabricating a semiconductor integrated circuit device comprising a stacked complementary transistor structure, according to another embodiment of the disclosure, wherein:

FIG. 9A is a schematic cross-sectional side view of an intermediate structure of the semiconductor integrated circuit device which, starting with the intermediate structure of FIG. 8G, is obtained after recessing initially deposited gate metallization to form a buried first metal gate electrode of the first transistor;

FIG. 9B is a schematic cross-sectional side view of an intermediate structure of the semiconductor integrated circuit device which is obtained after filling an open region above the buried first metal gate electrode with dielectric material to form a dielectric isolation layer;

FIG. 9C is a schematic cross-sectional side view of an intermediate structure of the semiconductor integrated circuit device which is obtained after removing sacrificial dielectric material to form a trench opening which exposes an underlying second stack of epitaxial semiconductor layers;

FIG. 9D is a schematic cross-sectional side view of an intermediate structure of the semiconductor integrated circuit device which is obtained after selectively etching away sacrificial layers of the second stack of epitaxial semiconductor layers to release nanosheet channel layers of a second transistor;

FIG. 9E is a schematic cross-sectional side view of an intermediate structure of the semiconductor integrated circuit device which is obtained after forming interfacial layers and high-k gate dielectric layers on exposed surfaces of the nanosheet channel layers of the second transistor;

FIG. 9F is a schematic cross-sectional side view of an intermediate structure of the semiconductor integrated circuit device which is obtained after forming a second metal gate electrode of the second transistor; and

FIG. 9G is a schematic cross-sectional side view of an intermediate structure of the semiconductor integrated circuit device which is obtained after forming a deep via in the dielectric isolation layer to provide a gate contact to the underlying first buried metal gate electrode of the of the first transistor.

FIGS. 10A-10H schematically illustrate a method for fabricating a semiconductor integrated circuit device comprising a stacked complementary transistor structure, according to an embodiment of the disclosure, wherein:

FIG. 10A is a schematic cross-sectional side view of an intermediate structure of the semiconductor integrated circuit device which comprises a first dummy gate and a second dummy gate that are to be replaced with a first metal gate and a second metal gate, respectively, of a first stacked complementary transistor structure and a second stacked complementary transistor structure; which are disposed adjacent to each other on a substrate;

FIG. 10B is a schematic cross-sectional side view of an intermediate structure of the semiconductor integrated circuit device which is obtained after forming a second high-k/metal gate structure of a second transistor of the second stacked complementary transistor structure within the second dummy gate;

FIG. 10C is a schematic cross-sectional side view of an intermediate structure of the semiconductor integrated circuit device which is obtained after forming a first high-k/metal gate structure of a first transistor of the first stacked complementary transistor structure;

FIG. 10D is a schematic cross-sectional side view of an intermediate structure of the semiconductor integrated circuit device which is obtained after selectively etching away a sacrificial dielectric material to form a trench opening which exposes a second stack of epitaxial semiconductor layers of a first patterned stack of epitaxial semiconductor layers, and after removing a remaining portion of the second dummy gate to form an open region which exposes a first stack of epitaxial semiconductor layers of the second patterned stack of epitaxial semiconductor layers;

FIG. 10E is a schematic cross-sectional side view of an intermediate structure of the semiconductor integrated circuit device which is obtained after selectively etching away sacrificial layers of the second stack of epitaxial semiconductor layers of the first patterned stack of epitaxial semiconductor layers, to release channel layers of a second transistor, and after selectively etching away sacrificial layers of the first stack of epitaxial semiconductor layers of the second patterned stack of epitaxial semiconductor layers to release channel layers of a first transistor;

FIG. 10F is a schematic cross-sectional side view of an intermediate structure of the semiconductor integrated circuit device which is obtained after forming interfacial layers and high-k gate dielectric layers on the exposed surfaces of the channel layers of the first transistor and on the exposed surfaces of the channel layers of the second transistor;

FIG. 10G is a schematic cross-sectional side view of an intermediate structure of the semiconductor integrated circuit device which is obtained after forming a second metal gate electrode which encapsulates the channel layers of the second transistor, after forming a first (buried) metal gate electrode which encapsulates the channel layers of the first transistor, and after forming a second dielectric isolation layer; and

FIG. 10H is a schematic cross-sectional side view of an intermediate structure of the semiconductor integrated circuit device which is obtained after forming a first horizontal metallic strap element on a front-side of the substrate, and after forming a second horizontal metallic strap element on a back-side of the substrate.

### DETAILED DESCRIPTION

Exemplary embodiments will now be described in further detail with regard semiconductor integrated circuit devices comprising stacked CMOS device structures (alternatively, stacked complementary transistor structures) with dual work function metal gates, and methods for fabricating such semiconductor integrated circuit devices. For illustrative purposes, exemplary embodiments of the disclosure will be discussed in the context of stacked complementary transistor structures comprising nanosheet MOSFET devices. It is to be understood, however, that the exemplary embodiments discussed herein are readily applicable to various types of gate-all-around (GAA) FET devices such as nanowire MOSFETs, and other types of GAA MOSFET devices having gate structures that are formed around all sides of active channel layers.

An exemplary embodiment includes a device which comprises a stacked transistor structure and a shared gate structure. The stacked transistor structure comprises a first transistor of a first type, and a second transistor of a second type which is opposite the first type, and disposed over the first transistor. The shared gate structure comprises a first metal gate structure of the first transistor, a second metal gate structure of the second transistor, and a metallic connection layer. The second metal gate structure is embedded in the first metal gate structure with a dielectric layer disposed between the first metal gate structure and the second metal gate structure. The metallic connection layer electrically connects upper regions of the first metal gate structure and the second metal gate structure.

Advantageously, the exemplary device architecture and associated integration scheme provides a stacked transistor structure having a shared gate structure in which the metal gate structures for the first and second transistors are fabricated separately to provide custom metal gate structures for the first and second transistors.

In another exemplary embodiment, which may be combined with one or more of the embodiments of the preceding paragraphs, the metallic connection layer comprises a metallic strap element that is disposed on an upper surface of the first metal gate structure and on an upper surface of the second metal gate structure.

In another exemplary embodiment, which may be combined with one or more of the embodiments of the preceding paragraphs, the metallic connection layer comprises a metallic plug element that is formed within an upper surface region of the first metal gate structure and within an upper surface region of the second metal gate structure.

In another exemplary embodiment, which may be combined with one or more of the embodiments of the preceding paragraphs, the first metal gate structure comprises a first gate dielectric layer, and a first work function metal layer which encapsulates at least one channel layer of the first transistor. The second metal gate structure comprises a second gate dielectric layer, and a second work function metal layer which encapsulates at least one channel layer of the second transistor. The dielectric layer disposed between the first metal gate structure and the second metal gate structure comprises a first residual dielectric layer comprised of dielectric material of the first gate dielectric layer, and a second residual dielectric layer comprised of dielectric material of the second gate dielectric layer.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor. The first interfacial layer and the second interfacial layer are formed of a same oxide material.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor. The first interfacial layer and the second interfacial layer are formed of different oxide materials.

In another exemplary embodiment, which may be combined with one or more of the embodiments of the preceding paragraphs, the first transistor and the second transistor each comprise a gate-all-around nanosheet field-effect transistor. The first transistor is a P-type transistor and the second transistor is an N-type transistor, or the first transistor is an N-type transistor and the second transistor is a P-type transistor.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a first metal gate structure of the first transistor, and a second metal gate structure of the second transistor. The second metal gate structure is embedded in the first metal gate structure with a dielectric layer disposed between the first metal gate structure and the second metal gate structure.

Advantageously, the exemplary device architecture and integration scheme provides a stacked transistor structure having a non-shared shared gate structure in which the metal gate structures for the first and second transistors are fabricated separately to provide custom metal gate structures for the first and second transistors.

In another exemplary embodiment, which may be combined with one or more of the embodiments of the preceding paragraphs, the first metal gate structure comprises a first gate dielectric layer, and a first work function metal layer which encapsulates at least one channel layer of the first transistor, and the second metal gate structure comprises a second gate dielectric layer, and a second work function metal layer which encapsulates at least one channel layer of the second transistor. The dielectric layer disposed between the first metal gate structure and the second metal gate structure comprises a first residual dielectric layer comprised of dielectric material of the first gate dielectric layer, and a second residual dielectric layer comprised of dielectric material of the second gate dielectric layer.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor, where the first interfacial layer and the second interfacial layer are formed of a same oxide material.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor, where the first interfacial layer and the second interfacial layer are formed of different oxide materials.

In another exemplary embodiment, which may be combined with one or more of the embodiments of the preceding paragraphs, the first transistor and the second transistor each comprise a gate-all-around nanosheet field-effect transistor. The first transistor is a P-type transistor and the second transistor is an N-type transistor, or the first transistor is an N-type transistor and the second transistor is a P-type transistor.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a dielectric isolation layer, a first metal gate structure of the first transistor, and a second metal gate structure of the second transistor. The second metal gate structure is embedded in the dielectric isolation layer with a dielectric layer comprised of gate dielectric material disposed between the second metal gate structure and the dielectric isolation layer. The first metal gate structure is disposed below the dielectric isolation layer.

In another exemplary embodiment, which may be combined with one or more of the embodiments of the preceding paragraphs, the first metal gate structure comprises a first gate dielectric layer, and a first work function metal layer which encapsulates at least one channel layer of the first transistor, and the second metal gate structure comprises a second gate dielectric layer, and a second work function metal layer which encapsulates at least one channel layer of the second transistor. The dielectric layer disposed between the second metal gate structure and the dielectric isolation layer comprises a first residual dielectric layer comprised of dielectric material of the first gate dielectric layer, and a second residual dielectric layer comprised of dielectric material of the second gate dielectric layer.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor, where the first interfacial layer and the second interfacial layer are formed of a same oxide material.

In another exemplary embodiment, which may be combined with one or more of the embodiments of the preceding paragraphs, the device further comprises a first interfacial layer disposed on a surface of the at least one channel layer of the first transistor, and a second interfacial layer disposed on a surface of the at least one channel layer of the second transistor, where the first interfacial layer and the second interfacial layer are formed of different oxide materials.

In another exemplary embodiment, which may be combined with one or more of the embodiments of the preceding paragraphs, the device further comprises a metallic via disposed in the dielectric isolation layer and in contact with the first metal gate structure.

In another exemplary embodiment, which may be combined with one or more of the embodiments of the preceding paragraphs, the first transistor and the second transistor each comprise a gate-all-around nanosheet field-effect transistor. The first transistor is a P-type transistor and the second transistor is an N-type transistor, or the first transistor is an N-type transistor and the second transistor is a P-type transistor.

Another exemplary embodiment includes a device which comprises a first stacked transistor structure and a second stacked transistor structure disposed on a substrate. The first stacked transistor structure comprises a first transistor of a first type, a second transistor of a second type which is opposite the first type, and disposed over the first transistor, and a first split gate structure. The first split gate structure comprises a first metal gate structure of the first transistor, and a second metal gate structure of the second transistor, wherein the first metal gate structure and the second metal gate structure are isolated from each other. The second stacked transistor structure comprises a third transistor of the second type, a fourth transistor of the first type and disposed over the third transistor, and a second split gate structure. The second split gate structure comprises a third metal gate structure of the third transistor, and a fourth metal gate structure of the fourth transistor, wherein the third metal gate structure and the fourth metal gate structure are isolated from each other. A first metallic connection element connects the second metal gate structure and the fourth metal gate structure.

Advantageously, the exemplary device architectures and associated integration schemes allow stacked transistor structures having a split gate structures to be utilized to fabricate cross-coupled gate configurations for staked transistor structures, while allowing the fabrication of custom metal gate structures for stacked transistor structures.

In another exemplary embodiment, which may be combined with one or more of the embodiments of the preceding paragraphs, the device further comprises a second metallic connection element which connects first metal gate structure and the third metal gate structure.

In another exemplary embodiment, which may be combined with one or more of the embodiments of the preceding paragraphs, the first metal gate structure and the third metal gate structure are disposed in contact with each other.

In another exemplary embodiment, which may be combined with one or more of the embodiments of the preceding paragraphs, the first split gate structure comprises a first dielectric isolation layer, the second metal gate structure of the second transistor is embedded in the first dielectric isolation layer, the first metal gate structure of the first transistor is disposed below the first dielectric isolation layer, the second split gate structure comprises a second dielectric isolation layer, the fourth metal gate structure of the fourth transistor is embedded in the second dielectric isolation layer, and the third metal gate structure of the third transistor is disposed below the second dielectric isolation layer.

Another exemplary embodiment includes a method for fabricating a semiconductor integrated circuit device. The method comprises forming a stacked transistor structure which comprises a first transistor of a first type, a second transistor of a second type, which is opposite the first type and disposed over the first transistor, and forming a gate structure which comprises a first metal gate structure of the first transistor, and a second metal gate structure of the second transistor, wherein the second metal gate structure is embedded in the first metal gate structure with a dielectric layer disposed between the first metal gate structure and the second metal gate structure.

In another exemplary embodiment, which may be combined with one or more of the embodiments of the preceding paragraphs, forming the gate structure comprises forming a shared gate structure by forming a metallic connection layer to electrically connect upper regions of the first metal gate structure and the second metal gate structure.

In another exemplary embodiment, which may be combined with one or more of the embodiments of the preceding paragraphs, forming the gate structure comprises forming a split gate structure by recessing the first metal gate structure to a level which is below the second metal gate structure, and forming a dielectric isolation layer which is disposed above the recessed first metal gate structure and which surrounds the second metal gate structure.

It is to be understood that the various layers, structures, and regions shown in the accompanying drawings are schematic illustrations that are not drawn to scale. In addition, for case of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the same or similar reference numbers are used throughout the drawings to denote the same or similar features, elements, or structures, and thus, a detailed explanation of the same or similar features, elements, or structures will not be repeated for each of the drawings. Further, the terms “about” or “substantially” as used herein with regard to thicknesses, widths, percentages, ranges, etc., are meant to denote being close or approximate to, but not exactly. For example, the term “about” or “substantially” as used herein implies that a small margin of error is present, such as 1% or less than the stated amount. The term “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

To provide spatial context to the different structural orientations of the semiconductor structures shown throughout the drawings, XYZ Cartesian coordinates are shown in each of the drawings. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

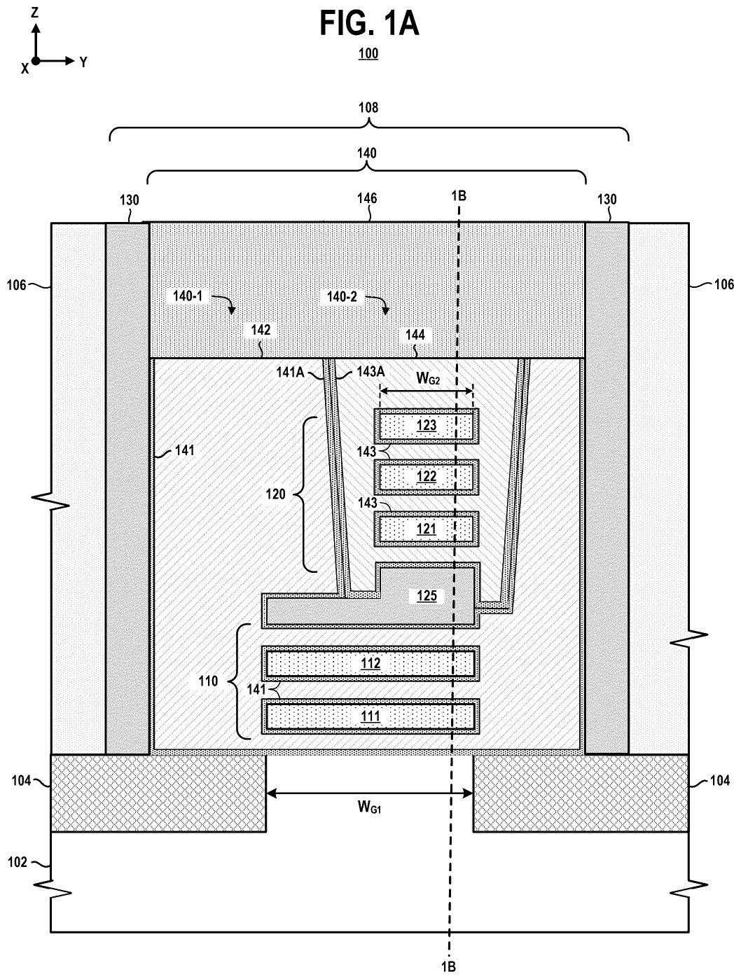

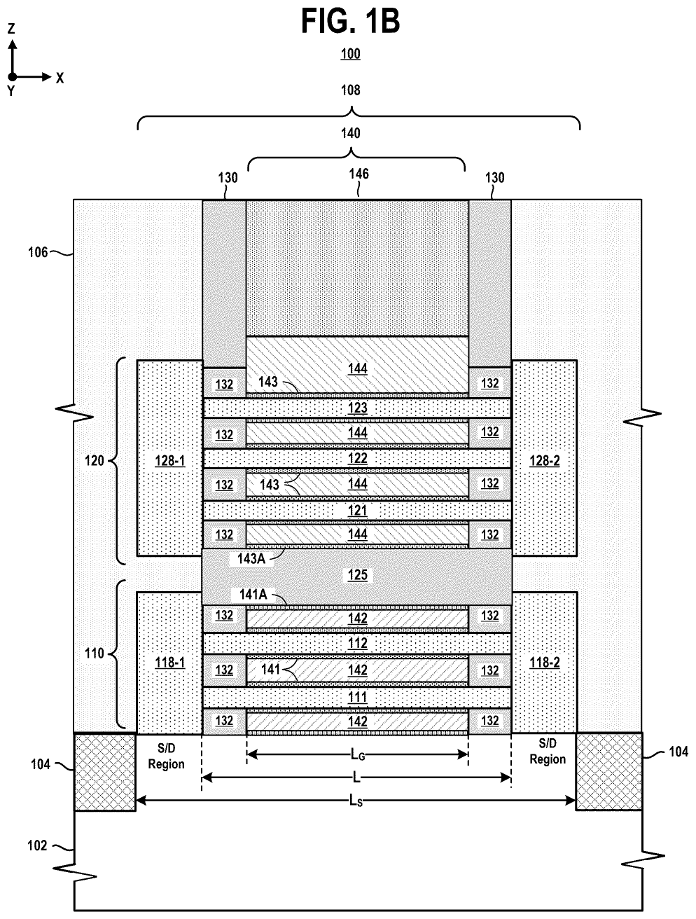

FIGS. 1A and 1B are schematic views of a semiconductor integrated circuit device 100 (or device 100) comprising a stacked complementary transistor structure, according to an exemplary embodiment of the disclosure. In particular, FIG. 1A is a schematic cross-sectional side view of the device 100 in a Y-Z plane, while FIG. 1B is a schematic cross-sectional side view of the device 100 in an X-Z plane along line 1B-1B in FIG. 1A. As collectively shown in FIGS. 1A and 1B, the device 100 comprises a substrate 102, a shallow trench isolation (STI) layer 104, a dielectric layer 106 (or pre-metallization dielectric layer 106), and a stacked complementary transistor structure 108 (e.g., stacked complementary FET structure). The stacked complementary transistor structure 108 comprises a first transistor 110, and a second transistor 120 disposed over the first transistor 110. The first transistor 110 and the second transistor 120 comprise complementary gate-all-around metal-oxide-semiconductor FET (MOSFET) devices (e.g., nanosheet FET devices). In some embodiments, the first transistor 110 comprises an N-type MOSFET, and the second transistor 120 comprises a P-type MOSFET. In other embodiments, the first transistor 110 comprises a P-type MOSFET, and the second transistor 120 comprises an N-type MOSFET.

The first transistor 110 comprises a plurality of channel layers 111 and 112 (e.g., nanosheet channel layers), a first source/drain element 118-1, and a second source/drain element 118-2. The second transistor 120 comprises a plurality of channel layers 121, 122, and 123, (e.g., nanosheet channel layers), a first source/drain element 128-1, and a second source/drain element 128-2. The channel layers of the first and second transistors 110 and 120 are separated by a dielectric isolation layer 125 (or middle dielectric isolation (MDI) layer 125) which can be formed of any suitable insulator or dielectric material, such as silicon nitride (SiN), silicon boron carbide nitride (SiBCN), silicon oxycarbonitride (SiOCN), etc.

As schematically shown in FIG. 1B, the first source/drain element 118-1 and the second source/drain element 118-2 are coupled to opposite ends of the channel layers 111 and 112 of the first transistor 110. In addition, the first source/drain element 128-1 and the second source/drain element 128-2 are coupled to opposite ends of the channel layers 121, 122, and 123 of the second transistor 120. It is to be understood that the term “source/drain element” of a given transistor as used herein means that a given source/drain element can be either a source element or a drain element of the given transistor, depending on the application or circuit configuration.

The stacked complementary transistor structure 108 further comprises a gate structure which comprises gate sidewall spacers 130 and 132, and a metal gate 140, wherein the metal gate 140 comprises a shared gate structure for the first and second transistors 110 and 120. In some embodiments, the metal gate 140 comprises a high-k/metal gate structure including a first metal gate 140-1 for the first transistor 110, and a second metal gate 140-2 for the second transistor 120. The first metal gate 140-1 comprises high-k gate dielectric layers 141 that are formed on the channel layers 111 and 112 of the first transistor 110, and a first metal gate electrode 142 which encapsulates the channel layers 111 and 112 of the first transistor 110. The second metal gate 140-2 comprises high-k gate dielectric layers 143 that are formed on the channel layers 121, 122, and 123 of the second transistor 120, and a second metal gate electrode 144 which encapsulates the channel layers 121, 122, and 123 of the second transistor 120.

In some embodiments, the first metal gate electrode 142 comprises a first work function metal which encapsulates the channel layers 111 and 112 of the first transistor 110, and the second metal gate electrode 144 comprises a second work function metal which encapsulates the channel layers 121, 122, and 123 of the second transistor 120. In some embodiments, the first metal gate electrode 142 is formed entirely of the first work function metal, and the second metal gate electrode 144 is formed entirely of the second work function metal. In some embodiments, the first metal gate electrode 142 comprises a first work function metal layer which encapsulates the channel layers 111 and 112 of the first transistor 110, and a low-resistance metallic material (e.g., tungsten) which is formed on the first work function metal layer. Moreover, in some embodiments, the second metal gate electrode 144 comprises a second work function metal layer which encapsulates the channel layers 121, 122, and 123 of the second transistor 120, and a low-resistance metallic material which is formed on the second work function metal layer. In some embodiments, the low-resistance metallic material comprises tungsten, while in other embodiments, the low-resistance metallic material may comprise, e.g., ruthenium, cobalt, copper, aluminum, etc.

As schematically shown in FIG. 1A, the first metal gate electrode 142 and the second metal gate electrode 144 are isolated (in part) by the MDI layer 125 and residual dielectric layers 141A and 143A that are formed during an exemplary fabrication process (as discussed in further detail below) when forming the high-k gate dielectric layers 141 and 143 on the respective channel layers of the first and second transistors 110 and 120. However, the metal gate 140 comprises a metallic strap 146 which provides an electrical connection between the first metal gate electrode 142 and the second metal gate electrode 144 to realize the shared metal gate structure of the metal gate 140. In some embodiments, the metallic strap 146 is formed of a low-resistance metallic material such as tungsten, while in other embodiments, the low-resistance metallic material may comprise, e.g., ruthenium, cobalt, copper, aluminum, etc.

The gate sidewall spacers 130 and 132 define a common gate region of the first transistor 110 and the second transistor 120, which surrounds/contains the metal gate 140. The gate sidewall spacer 130 serves to electrically insulate the metal gate 140 from surrounding elements (e.g., dielectric layer 106, and source/drain contacts (not shown)). Moreover, as schematically shown in FIG. 1B, the gate sidewall spacers 132 comprise embedded gate sidewall spacers (or internal spacers) which are formed between end portions of the channel layers 111, 112, 121, 122, and 123. The gate sidewall spacers 132 serve to (i) insulate the metallization of the first metal gate electrode 142 from the first and second source/drain elements 118-1 and 118-2 of the first transistor 110, and (ii) insulate the metallization of the second metal gate electrode 144 from the first and second source/drain elements 128-1 and 128-2 of the second transistor 120.

As shown in FIG. 1B, the metal gate 140 encapsulates portions of the channel layers 111, 112, 121, 122, and 123, which define a gate length (LG) of the first and second transistors 110 and 120, although the channel layers 111, 112, 121, 122, and 123 are physically longer (length L) than the gate length L_{G}. Moreover, as shown in FIG. 1A, the first transistor 110 comprises a first gate width W_{G1}, and the second transistor 120 comprises a second gate width W_{G2}. In some embodiments, the first gate width W_{G1} of the first transistor 110 is greater than the second gate width W_{G2} of the second transistor 120. It is to be noted that FIGS. 1A and 1B illustrate a non-limiting, exemplary embodiment of a stacked complementary transistor structure in which the first transistor 110 (e.g., N-type MOSFET) and the second transistor (e.g., P-type MOSFET) have different structural configurations (e.g., different number of channel layers, different gate widths, etc.) that are designed to achieve certain properties for certain applications. However, in other embodiments, the first and second transistors 110 and 120 can have the same number of channel layers, the same gate widths, and the same gate lengths. In other embodiments, the first and second transistors 110 and 120 can have different numbers of channel layers, and have the same gate widths and same gate lengths. In this regard, it is to be noted that the exemplary fabrication methods as discussed herein can be utilized to fabricate stacked complementary transistor structures regardless of the different structural configurations (e.g., different number of channel layers, different gate widths, etc.) of the first and second transistors 110 and 120.

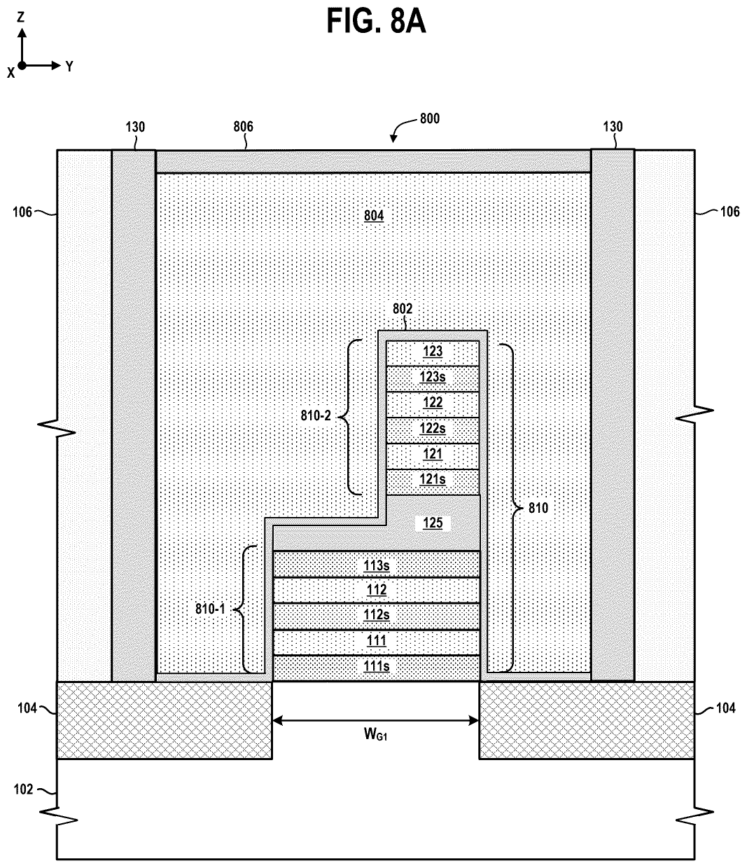

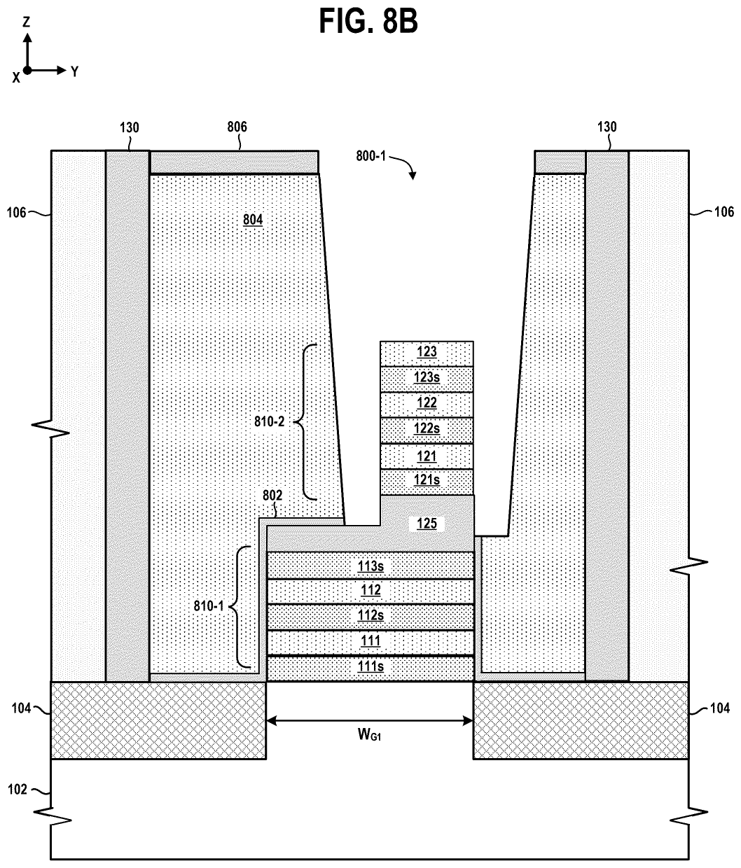

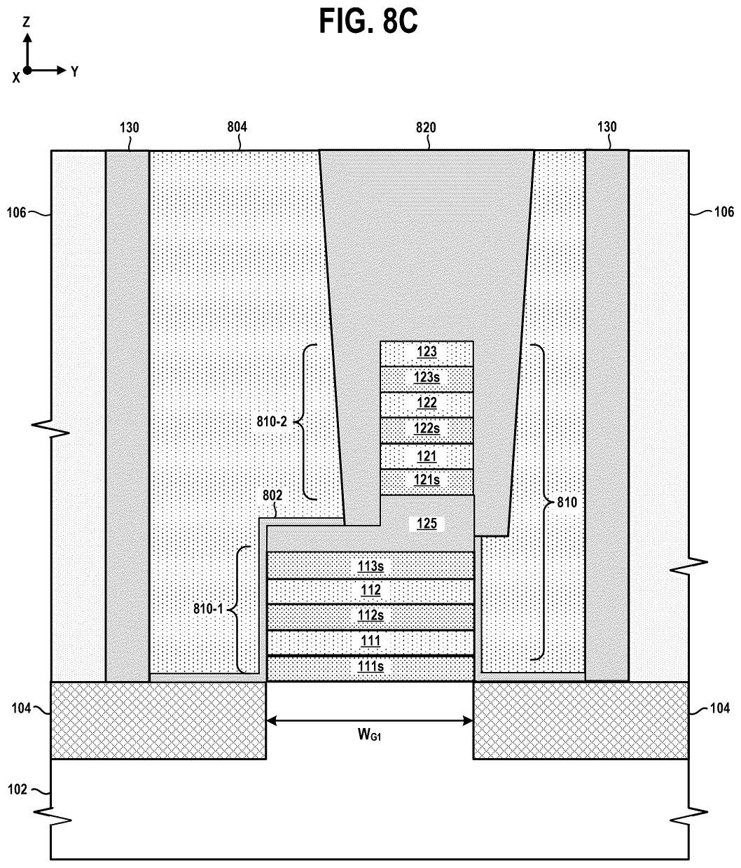

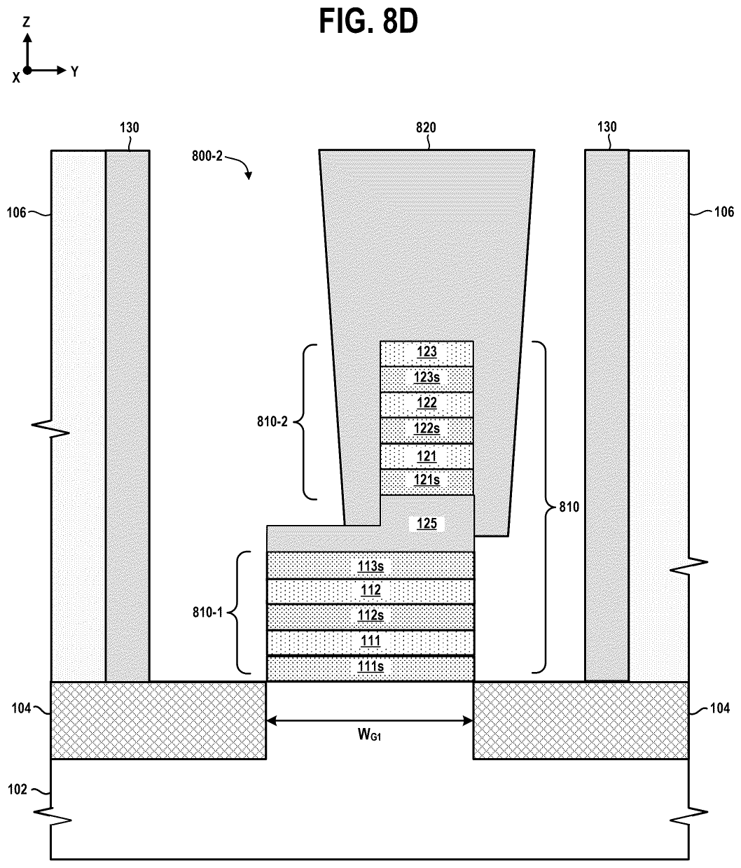

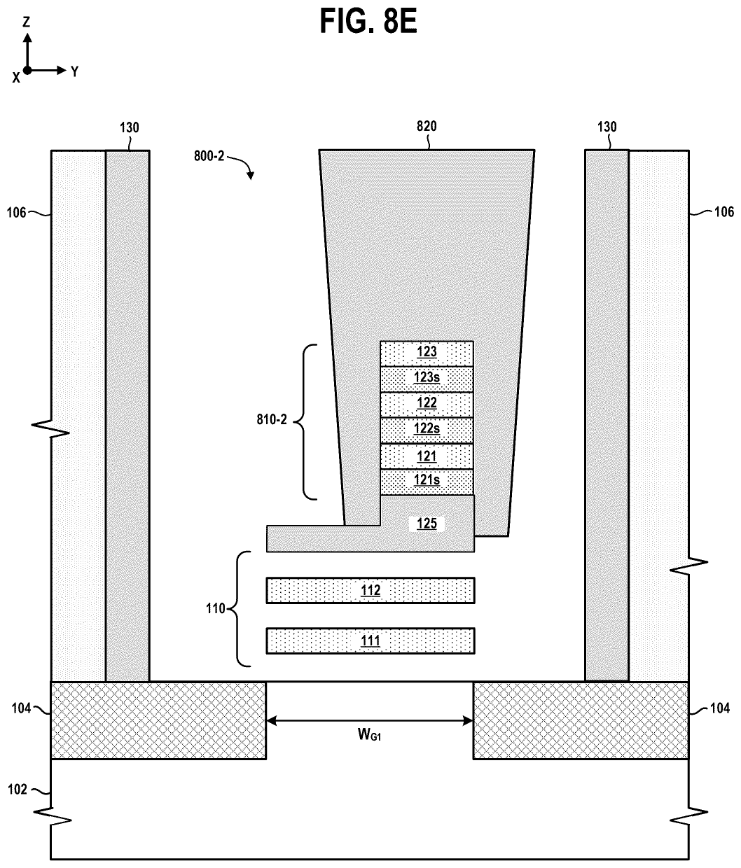

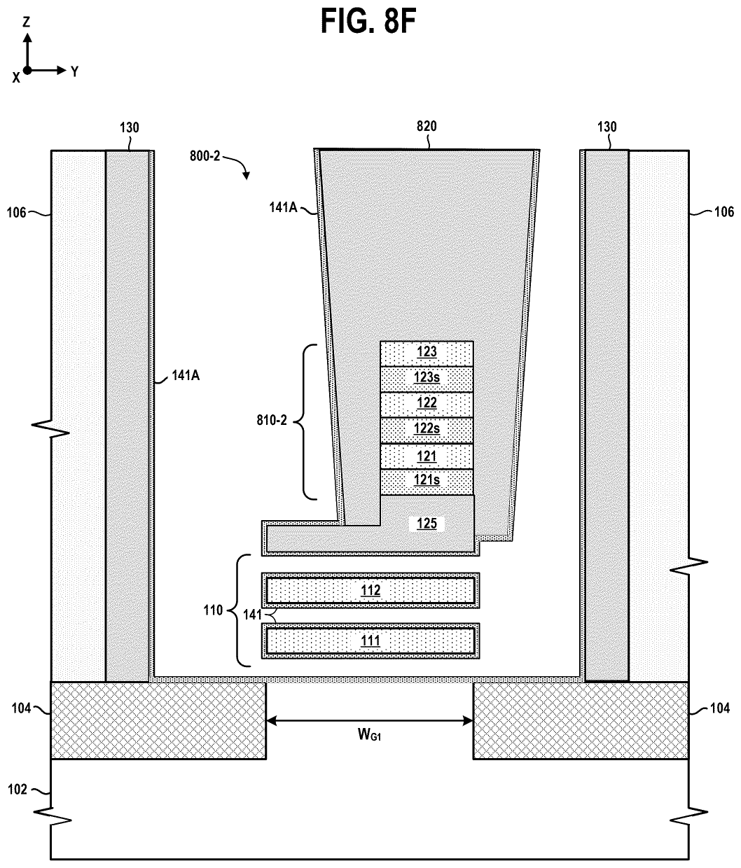

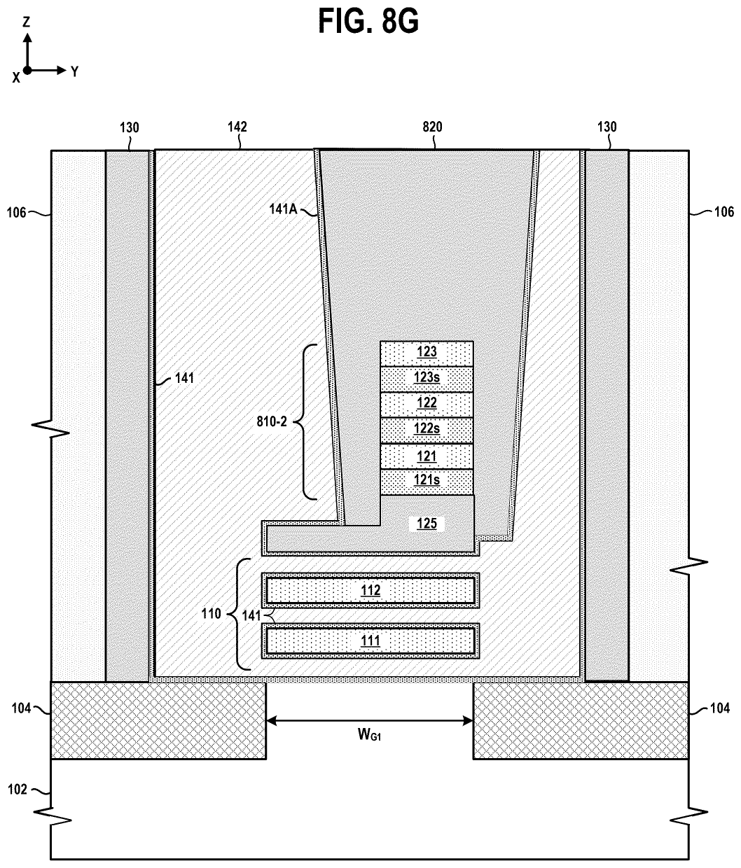

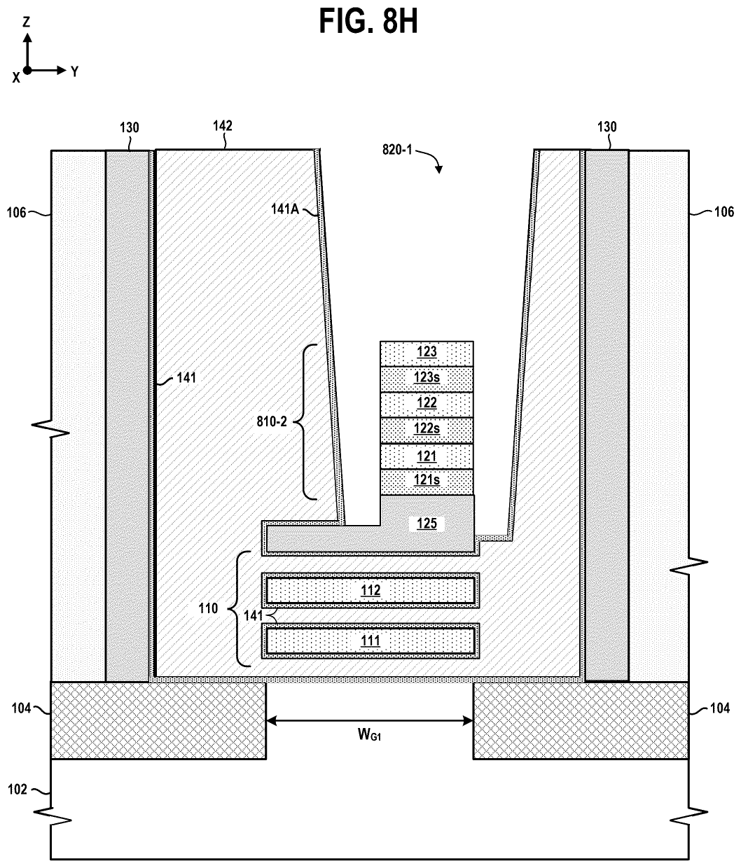

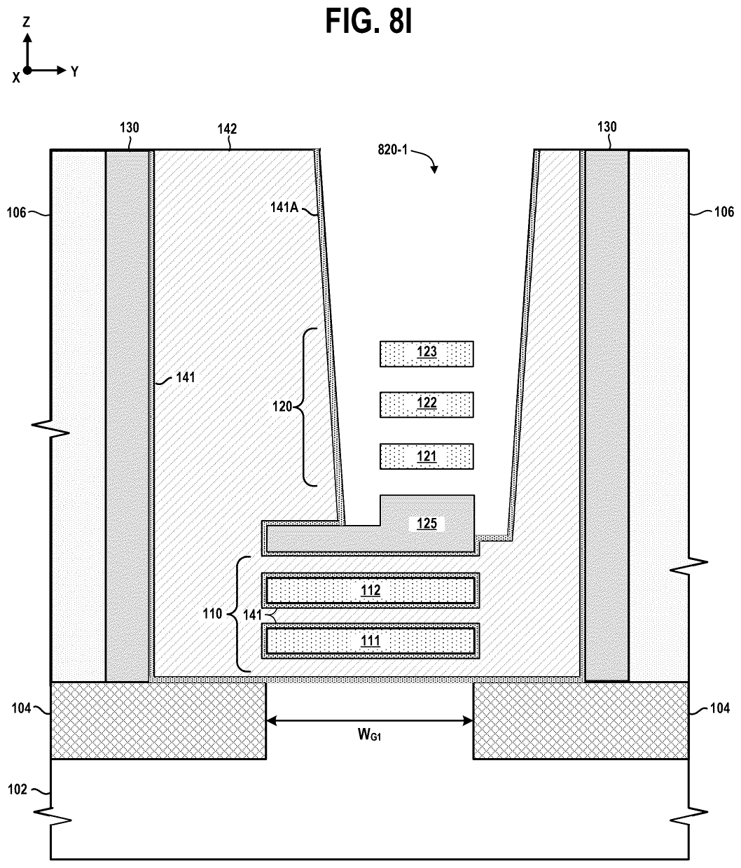

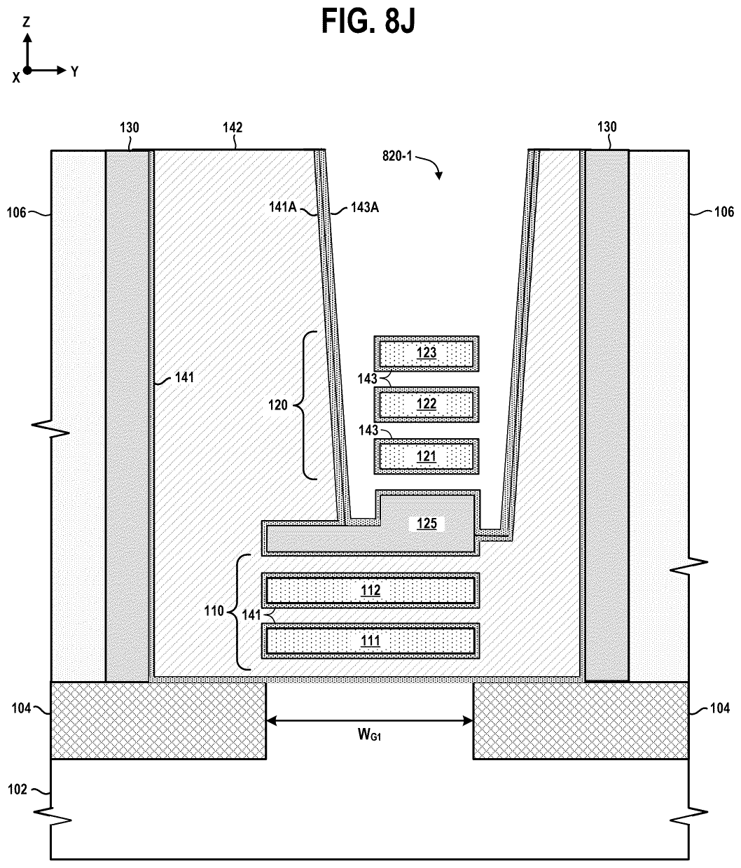

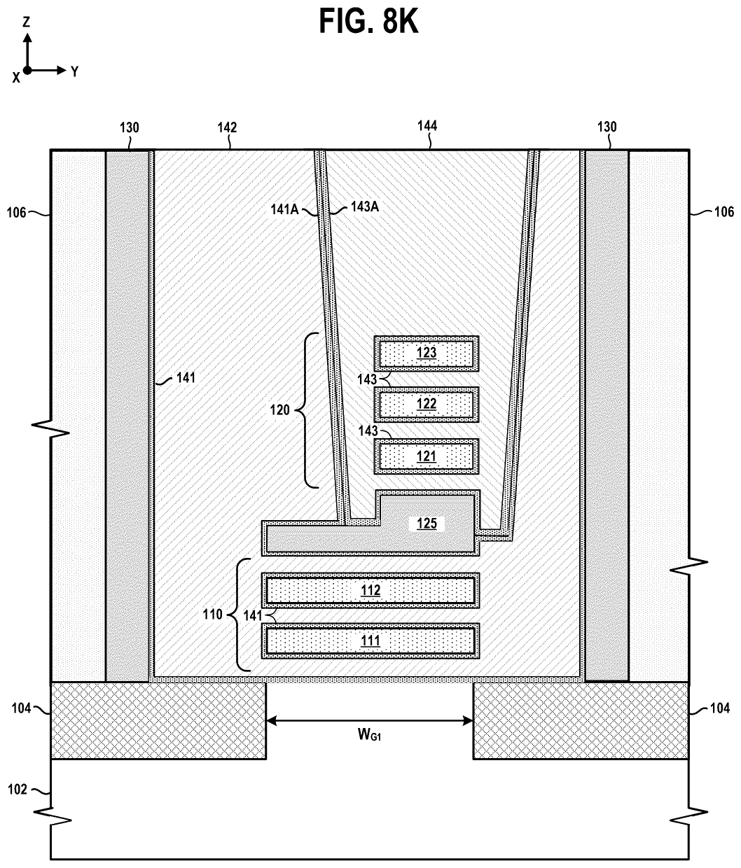

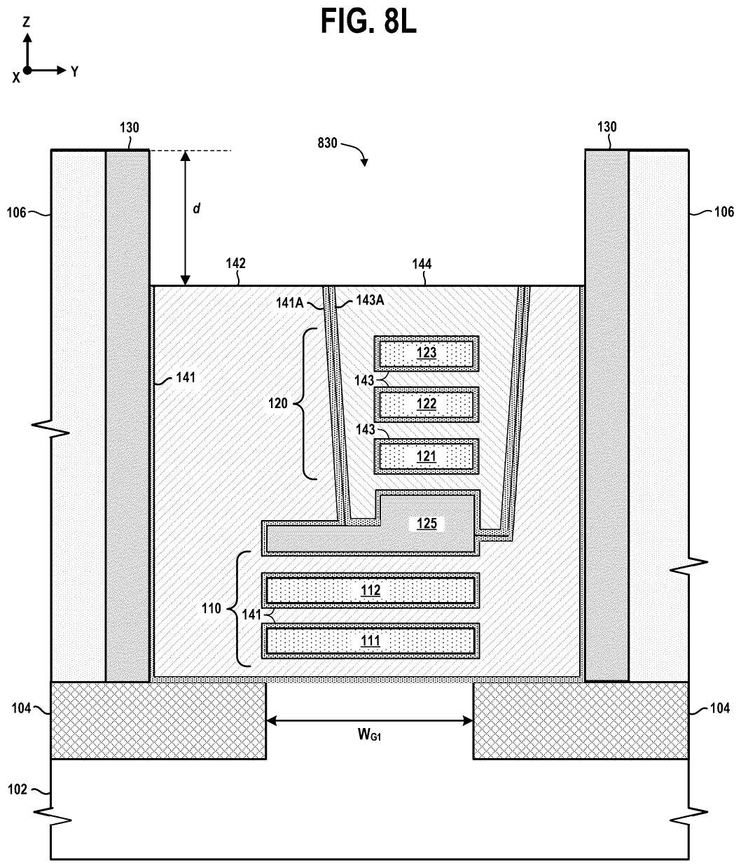

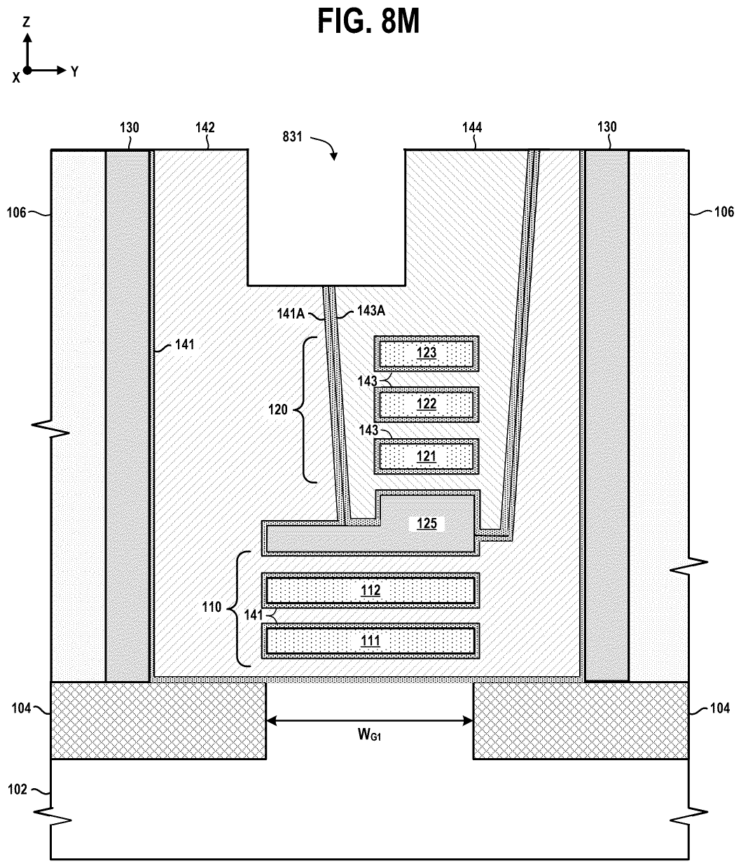

As is known in the art, the electrical properties of the first and second transistors 110 and 120, such as the threshold voltages (Vt) of the transistors, are based at least in part on the spacing between the nanosheet channel layers and the types of work function metals disposed in the spaces above and below the nanosheet channel layers of the transistors. In this regard, work function engineering through the implementation of dual work function metal layers for the first and second transistors 110 and 120 ensures the desired electrical properties of stacked complementary transistor structures. An exemplary process for fabricating the stacked complementary transistor structure 108 of FIGS. 1A and 1B (as will be discussed below in conjunction with FIGS. 8A through 8M) which allows the first metal gate 140-1 and the second metal gate 140-2 to be separately fabricated with, e.g., dual work function metals, etc., to optimize the electrical properties of the first and second transistors 110 and 120 of the stacked complementary transistor structure 108.

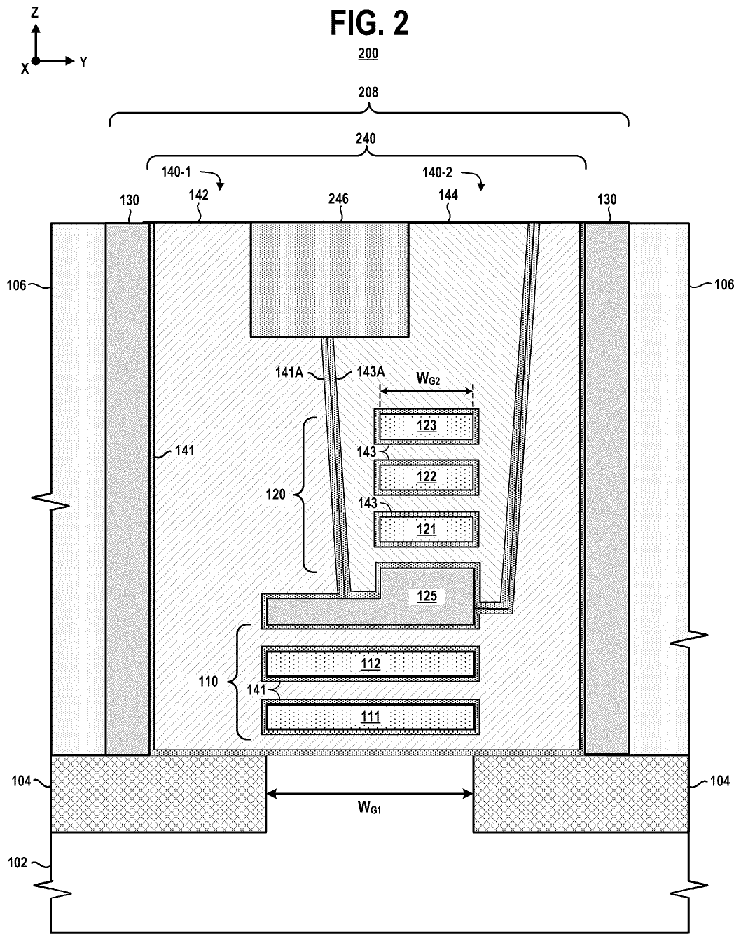

FIG. 2 is schematic cross-sectional side view (Y-Z plane) of a semiconductor integrated circuit device 200 (or device 200) comprising a stacked complementary transistor structure, according to another exemplary embodiment of the disclosure. The semiconductor integrated circuit device 200 is similar to the semiconductor integrated circuit device 100 as discussed above in that device 200 comprises the substrate 102, the STI layer 104, the pre-metallization dielectric layer 106, etc. However, the semiconductor integrated circuit device 200 comprises a stacked complementary transistor structure 208 (e.g., stacked complementary FET structure) having metal gate 240 which comprises a shared metal gate structure, which is slightly different from the shared metal gate structure of the metal gate 140 of FIGS. 1A and 1B. In particular, the metal gate 240 comprises a metallic plug 246 (as opposed to the metallic strap 146) to provide an electrical connection between the first metal gate electrode 142 and the second metal gate electrode 144 and thereby implement a shared metal gate structure. In some embodiments, the metallic plug 246 is formed of a low-resistance metallic material such as tungsten, while in other embodiments, the low-resistance metallic material may comprise, e.g., ruthenium, cobalt, copper, aluminum, etc.

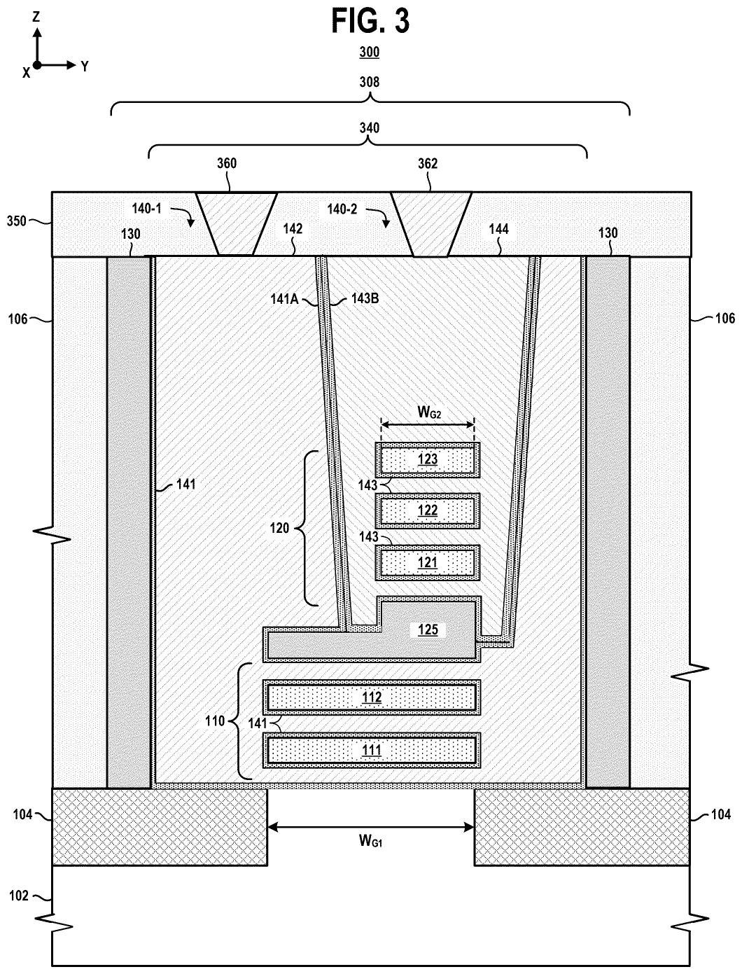

FIG. 3 is schematic cross-sectional side view (Y-Z plane) of a semiconductor integrated circuit device 300 comprising a stacked complementary transistor structure, according to another exemplary embodiment of the disclosure. The semiconductor integrated circuit device 300 is similar to the semiconductor integrated circuit device 100 as discussed above in that device 300 comprises the substrate 102, the STI layer 104, the pre-metallization dielectric layer 106, etc. However, the semiconductor integrated circuit device 300 comprises a stacked complementary transistor structure 308 which comprises a metal gate 340 having an exemplary split gate configuration (or non-shared gate structure) in which the metal gates of the first and second transistors 110 and 120 are not shared. In particular, the exemplary split gate configuration of the metal gate 340 is realized by the first metal gate electrode 142 and the second metal gate electrode 144 being isolated by the MDI layer 125 and the residual dielectric layers 141A and 143A that are formed as a result of forming the high-k gate dielectric layers 141 and 143. In this regard, the exemplary split gate configuration of the metal gate 340 is achieved by not forming the metallic strap 146 (in FIGS. 1A and 1B) or the metallic plug 246 (FIG. 2).

As further shown in FIG. 3, the semiconductor integrated circuit device 300 (or device 300) further comprises a middle-of-the-line (MOL) layer that is formed on the pre-metallization dielectric layer 106. The MOL layer comprises an interlevel dielectric (ILD) layer 350, and gate electrode contacts 360 and 362 (which can be lines or via plugs) which are in ohmic contact with the first metal gate electrode 142 and the second metal gate electrode 144, respectively. The gate electrode contacts 360 and 362 facilitate local connections to the first metal gate 140-1 and the second metal gate 140-2, respectively, of the first and second transistors 110 and 120.

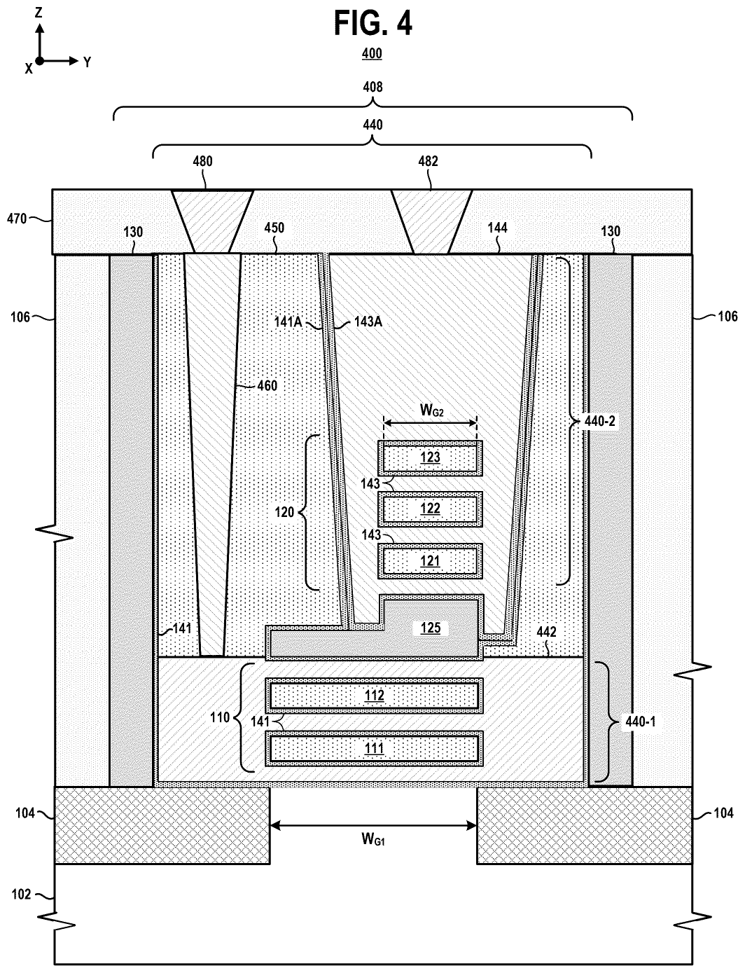

FIG. 4 is schematic cross-sectional side view (Y-Z plane) of a semiconductor integrated circuit device 400 (or device 400) comprising a stacked complementary transistor structure, according to another exemplary embodiment of the disclosure. The semiconductor integrated circuit device 400 is similar to the semiconductor integrated circuit device 100 as discussed above in that device 400 comprises the substrate 102, the STI layer 104, the pre-metallization dielectric layer 106, etc. However, the semiconductor integrated circuit device 400 comprises a stacked complementary transistor structure 408 which comprises a metal gate 440 having an exemplary split gate configuration. The metal gate 440 comprises a first metal gate 440-1 for the first transistor 110, and a second metal gate 440-2 for the second transistor 120.

The second metal gate 440-2 is essentially the same as the second metal gate 140-2 illustrated in the previous embodiments, wherein the second metal gate 440-2 comprises the high-k gate dielectric layers 143 and the second metal gate electrode 144, which encapsulate the channel layers 121, 122, and 123 of the second transistor 120. The first metal gate 440-1 is similar to the first metal gate 140-1 illustrated in the previous embodiments, in that the first metal gate comprises the high-k gate dielectric layers 141 formed on the channel layers 111 and 112 of the first transistor 110. However, the first metal gate 440-1 as shown in FIG. 4 comprises a buried first metal gate electrode 442, which encapsulates the channel layers 111 and 112 of the first transistor 110. In addition, the metal gate 440 comprises a dielectric isolation layer 450 which is disposed over the first metal gate 440-1, and which surrounds the second metal gate 440-2. The exemplary split gate configuration of the metal gate 440 is realized by isolating the first metal gate 440-1 and the second metal gate 440-2 from each other by the MDI layer 125, the residual dielectric layers 141A and 143A, and the dielectric isolation layer 450.

As further shown in FIG. 4, a deep via 460 is disposed in the dielectric isolation layer 450 to provide a gate contact to the underlying (buried) first metal gate 440-1. In addition, the semiconductor integrated circuit device 400 further comprises a MOL layer which comprises an ILD layer 470, and gate contacts 480 and 482 (which can be lines or via plugs). The gate contact 480 is connected to the deep via 460, and the gate contact 482 is connected to second metal gate electrode 144. The gate contacts 480 and 482 facilitate local connections to the first metal gate 440-1 and the second metal gate 440-2, respectively, of the first and second transistors 110 and 120.

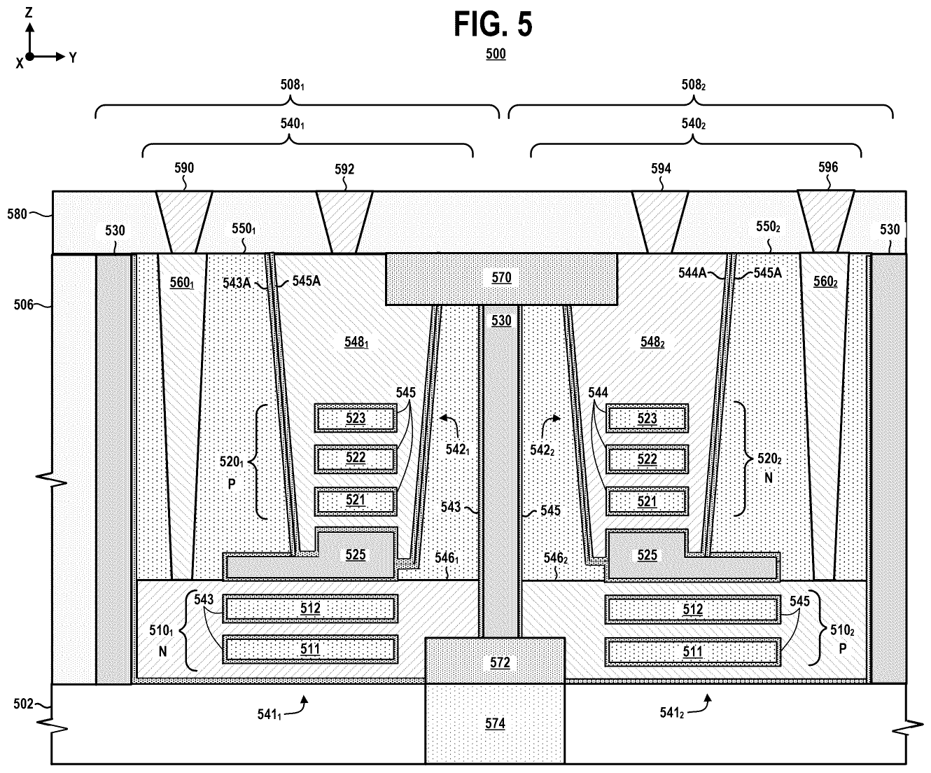

FIG. 5 is a schematic cross-sectional side view of a semiconductor integrated circuit device comprising a pair of stacked complementary transistor structures which enable a cross-coupled gate configuration, according to an exemplary embodiment of the disclosure. In particular, FIG. 5 schematically illustrates a semiconductor integrated circuit device 500 which comprises a substrate 502, a pre-metallization dielectric layer 506, a first stacked complementary transistor structure 508₁, and a second stacked complementary transistor structure 508₂, wherein the first and second stacked complementary transistor structures 508₁ and 508₂ are disposed adjacent to each other on the substrate 502.

The first stacked complementary transistor structure 508₁ comprises a first transistor 510₁ and a second transistor 520₁ which is disposed over the first transistor 510₁. Similarly, the second stacked complementary transistor structure 508₂ comprises a first transistor 510₂ and a second transistor 520₂ which is disposed over the first transistor 510₂. In some embodiments, as schematically shown in FIG. 5, the first and second stacked complementary transistor structures 508₁ and 508₂ have stacked transistor architectures that are structural duplicates but disposed adjacent to each other in a mirrored configuration. In the exemplary non-limiting embodiment show, the first (bottom) transistors 510₁ and 510₂ each comprise two channel layers 511 and 512, and the second (upper) transistors 520₁ and 520₂ each comprise three channel layers 521, 522, and 523, wherein the stack of channel layers of the upper and bottom transistor are isolated by MDI layer 525.

In addition, the first stacked complementary transistor structure 508₁ and the second stacked complementary transistor structure 508₂ comprise respective gate regions defined by gate sidewall spacers 530. In particular, the first stacked complementary transistor structure 508₁ comprises a first metal gate 540₁, and the second stacked complementary transistor structure 508₂ comprises a second metal gate 540₂. In the exemplary embodiment shown, the first and second metal gates 540₁ and 540₂ each comprise an exemplary split gate architecture which is similar to the exemplary split gate architecture of the metal gate 440 as shown and discussed above in conjunction with FIG. 4.

In particular, the first metal gate 540₁ of the first stacked complementary transistor structure 508₁ comprises a first metal gate 541₁ for the first transistor 510₁, and a second metal gate 542₁ for the second transistor 520₁. The first metal gate 541₁ comprises high-k gate dielectric layers 543 formed on the channel layers 511 and 512 of the first transistor 510₁, and a first metal gate electrode 546₁ which encapsulates the channel layers 511 and 512 of the first transistor 510₁. The second metal gate 542₁ comprises high-k gate dielectric layers 545 formed on the channel layers 521, 522, and 523 of the second transistor 520₁, and a second metal gate electrode 548₁ which encapsulates the channel layers 521, 522, and 523 of the second transistor 520₁.

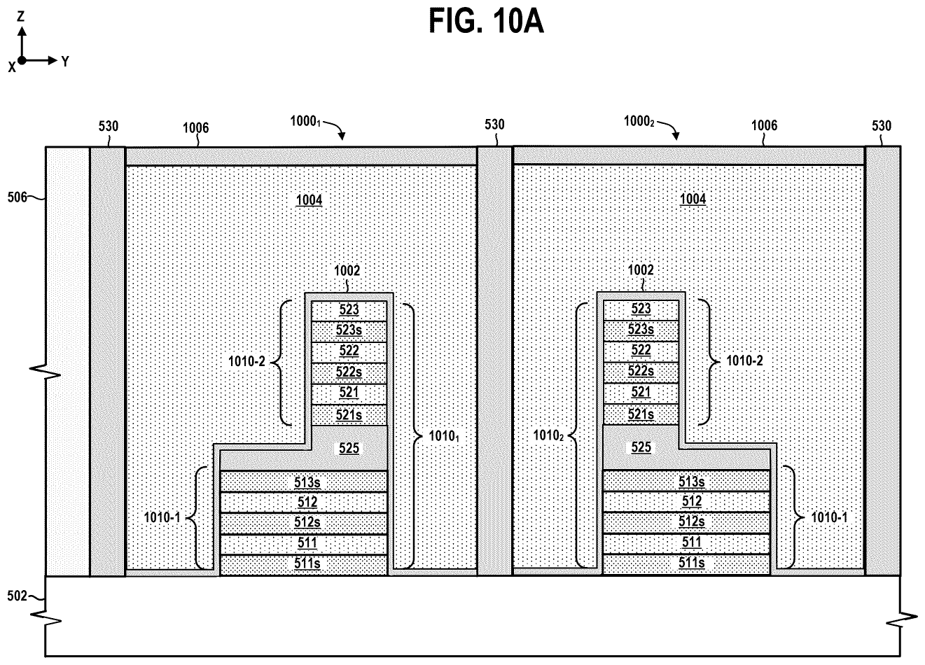

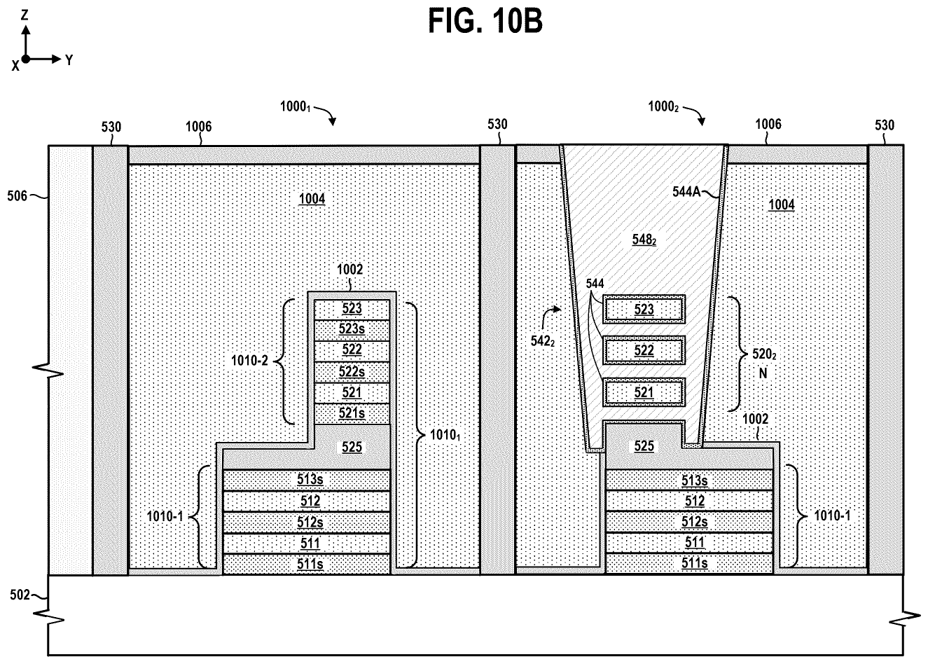

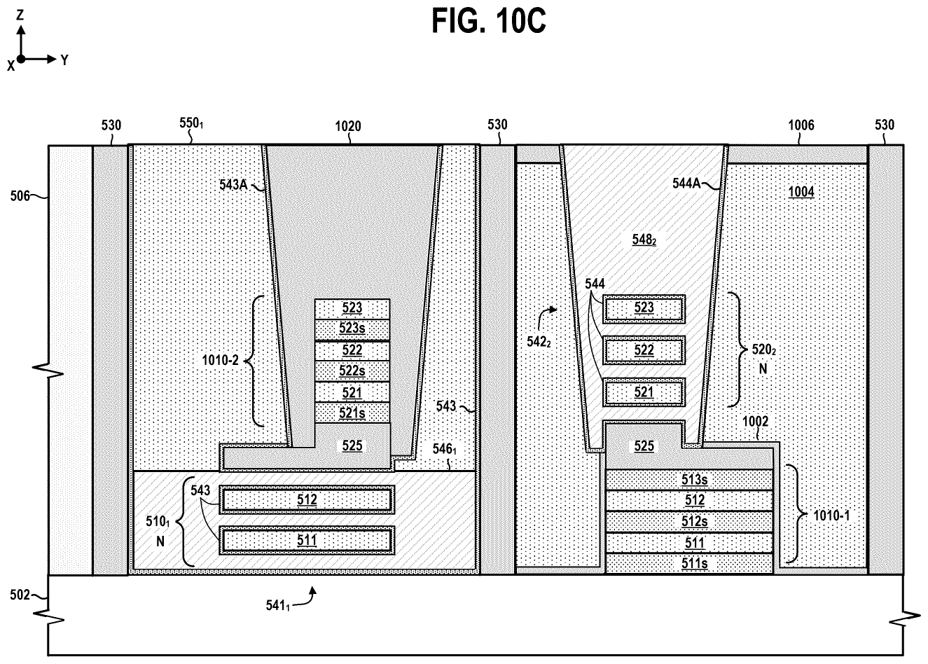

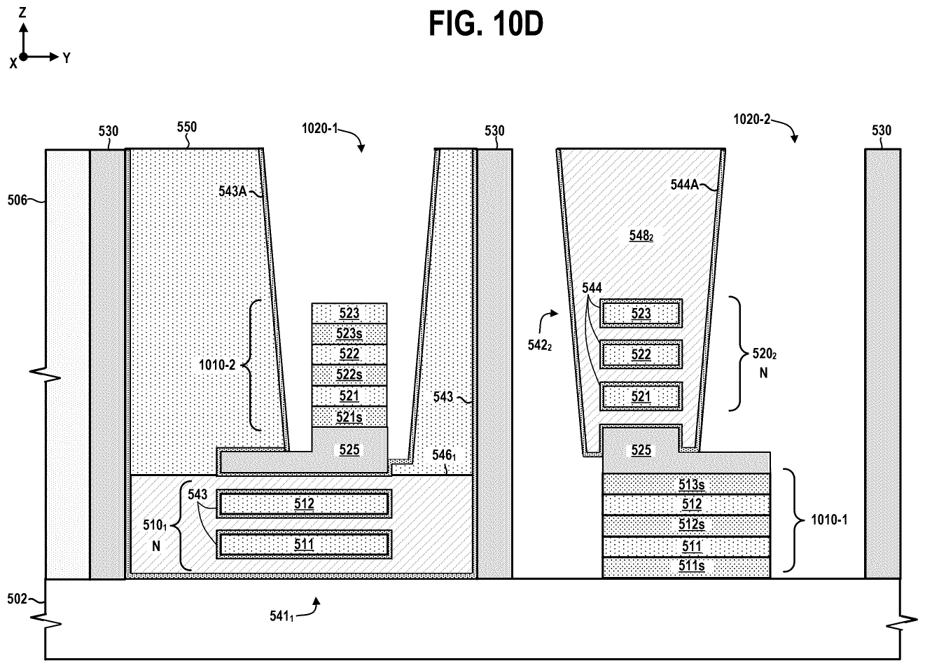

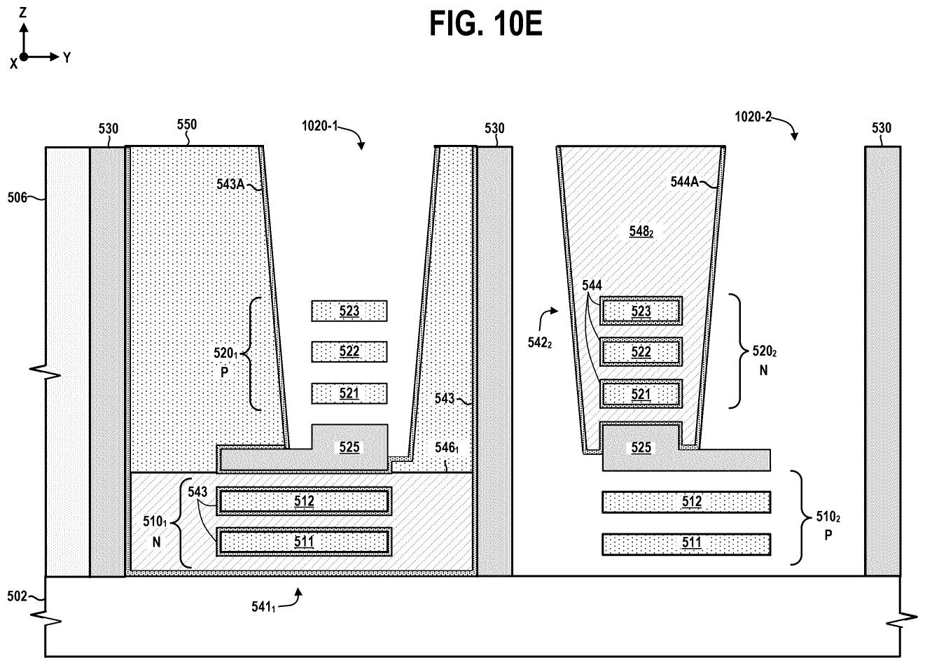

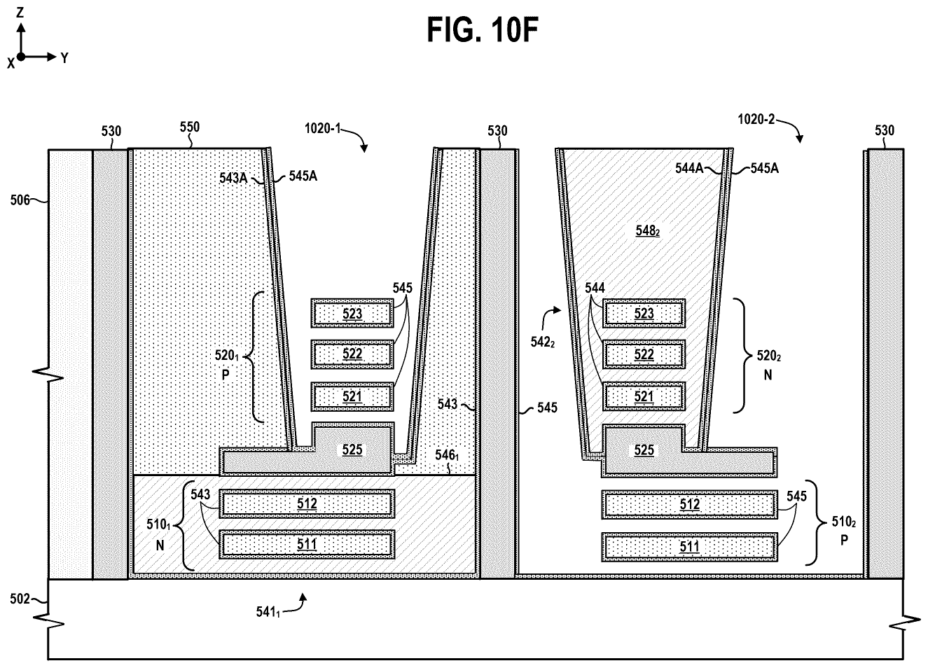

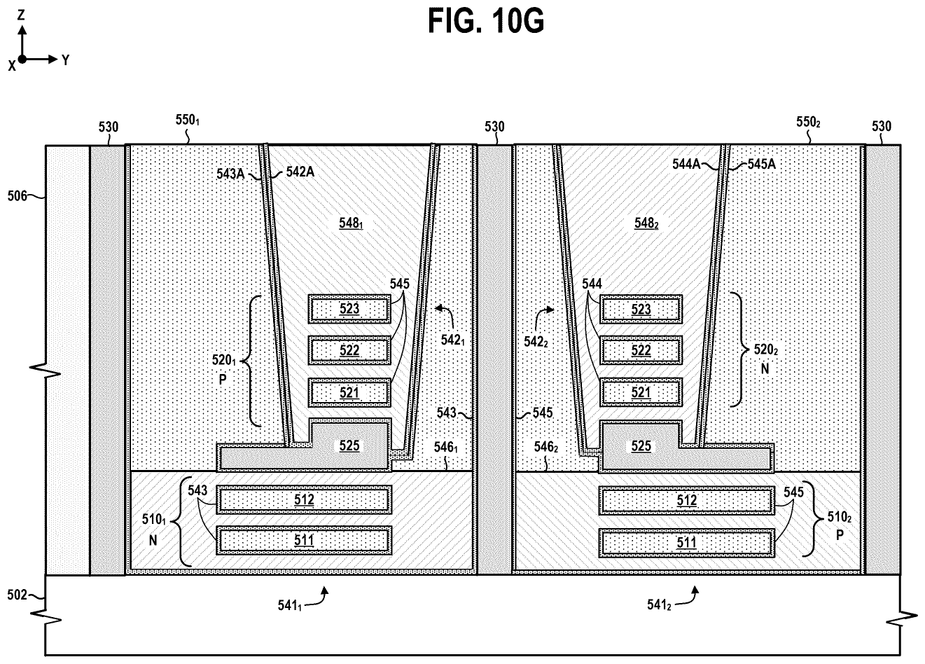

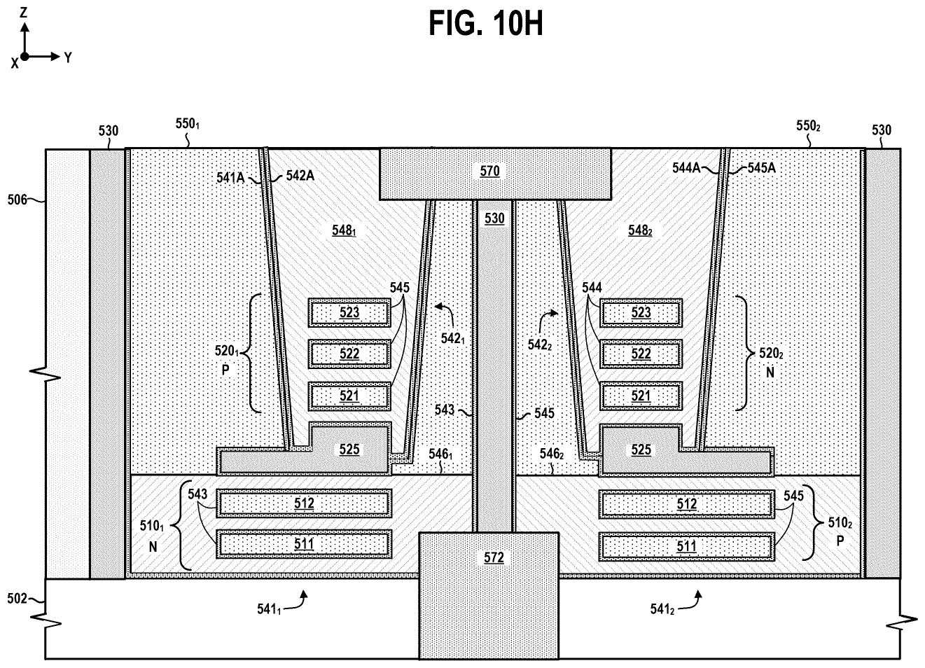

Similarly, the second metal gate 540₂ of the second stacked complementary transistor structure 508₂ comprises a first metal gate 541₂ for the first transistor 510₂, and a second metal gate 542₂ for the second transistor 520₂. The first metal gate 541₂ comprises high-k gate dielectric layers 545 formed on the channel layers 511 and 512 of the first transistor 510₂, and a first metal gate electrode 546₂ which encapsulates the channel layers 511 and 512 of the first transistor 510₂. The second metal gate 542₂ comprises high-k gate dielectric layers 544 formed on the channel layers 521, 522, and 523 of the second transistor 520₂, and a second metal gate electrode 548₂ which encapsulates the channel layers 521, 522, and 523 of the second transistor 520₂. In some embodiments, the high-k gate dielectric layers 545 disposed on the channel layers 511 and 512 of the first transistor 510₂ (of the second stacked complementary transistor structure 508₂) and on the channel layers 521, 522, and 523 of the second transistor 520₁ (of the first stacked complementary transistor structure 508₁) are concurrently formed (see FIG. 10) in an exemplary fabrication process, as will be discussed in further detail below.

As further shown in FIG. 5, the first stacked complementary transistor structure 508₁ comprises a first dielectric isolation layer 550₁ which is disposed over the first metal gate 541₁ of the first transistor 510₁, and which surrounds the second metal gate 542₁ of the second transistor 520₁. Similarly, the second stacked complementary transistor structure 508₂ comprises a second dielectric isolation layer 550₂ which is disposed over the first metal gate 541₂ of the first transistor 510₂, and which surrounds the second metal gate 542₂ of the second transistor 520₂.

The first metal gate 540₁ comprises an exemplary split gate architecture in which the first metal gate 541₁ and the second metal gate 542₁ are electrically isolated by the MDI layer 525, residual dielectric layers 543A and 545A, and the first dielectric isolation layer 550₁. Similarly, the second metal gate 540₂ comprises an exemplary split gate architecture in which the first metal gate 541₂ and the second metal gate 542₂ are electrically isolated by the MDI layer 525, residual dielectric layers 544A and 545A, and the second dielectric isolation layer 550₂. As further shown in FIG. 5, a first deep via 560₁ is disposed in the first dielectric isolation layer 550₁ to provide a gate contact to the underlying (buried) first metal gate 541₁. Similarly, a second deep via 560₂ is disposed in the second dielectric isolation layer 550₂ to provide a gate contact to the underlying (buried) first metal gate 541₂.

In some embodiments, an exemplary cross-coupled gate configuration of FIG. 5 is realized by designing the first (bottom) transistors 510₁ and 510₂ to be different device types (opposite polarity) and designing the second (upper) transistors 520₁ and 520₂ to be different device types (opposite polarity). For example, in some embodiments as shown in FIG. 5, for the first stacked complementary transistor structure 508₁, the first transistor 510₁ is an N-type MOSFET, and the second transistor 520₁ is a P-type MOSFET, whereas for the second stacked complementary transistor structure 508₂, the first transistor 510₂ is a P-type MOSFET, and the second transistor 520₂ is an N-type MOSFET. However, in alternative embodiments, for the first stacked complementary transistor structure 508₁, the first transistor 510₁ is a P-type MOSFET, and the second transistor 520₁ is an N-type MOSFET, whereas for the second stacked complementary transistor structure 508₂, the first transistor 510₂ is an N-type MOSFET, and the second transistor 520₂ is a P-type MOSFET.

Moreover, as schematically shown in FIG. 5, the second metal gates 542₁ and 542₂ of the respective second (upper) transistors 520₁ and 520₂ are electrically connected by a first horizontal metallic strap element 570 which crosses over a gate-cut region defined by the gate sidewall spacers 530, on the front-side of the substrate 502. In other words, the first horizontal metallic strap element 570 is configured to connect the metal gates of the second (upper) transistors 520₁ and 520₂. Moreover, the first metal gates 541₁ and 541₂ of the respective first (bottom) transistors 510₁ and 510₂ are electrically connected by a second horizontal metallic strap element 572 on the back-side of the substrate 502, which crosses under the gate-cut region defined by the middle sidewall spacer of the gate sidewall spacers 530. The second horizontal metallic strap element 572 can be formed using a back-side fabrication process in which a back-side trench is formed through the back-side of the substrate 502 and partially into the first metal gates 541₁ and 541₂ of the respective first (bottom) transistors 510₁ and 510₂, and then filled with a low resistance metallic material (e.g., tungsten) to form the second horizontal metallic strap element 572. In some embodiments, an insulating plug 574 can be formed in the back-side of the substrate 502 by partially recessing the metal in the back-side trench, and then filling the recess with insulating material to form the insulating plug 574.

As further shown in FIG. 5, the semiconductor integrated circuit device 500 further comprises a MOL layer which comprises an ILD layer 580, and gate contacts 590, 592, 594, and 596 (which can be lines or via plugs). The gate contact 590 is connected to the first deep via 560₁, the gate contact 592 is connected to the second metal gate electrode 548₁, the gate contact 594 is connected to the second metal gate electrode 548₂, and the gate contact 596 is connected to the second deep via 560₂. The gate contacts 590, 592, 594, and 596 facilitate local connections to the gates of the transistors of the first and second stacked complementary transistor structures 508₁ and 508₂.

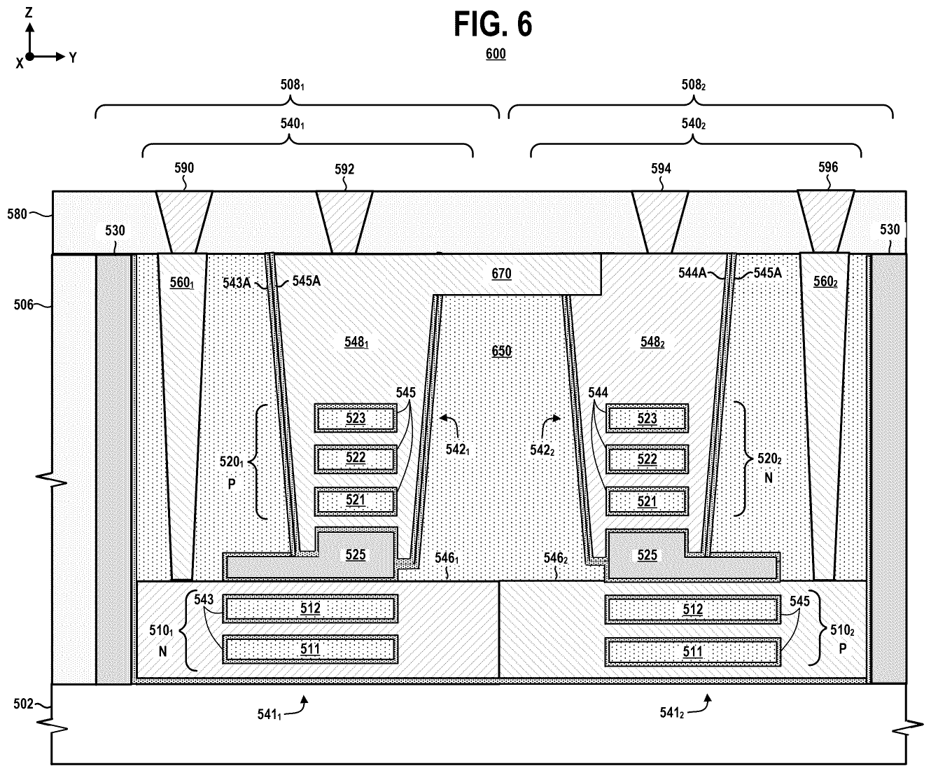

FIG. 6 is a schematic cross-sectional side view of a semiconductor integrated circuit device comprising a pair of stacked complementary transistor structures which enable a cross-coupled gate configuration, according to another exemplary embodiment of the disclosure. In particular, FIG. 6 schematically illustrates a semiconductor integrated circuit device 600 which is similar to the semiconductor integrated circuit device 500 of FIG. 5. Except that the first stacked complementary transistor structure 508₁, and the second stacked complementary transistor structure 508₂ are disposed adjacent to each other on the substrate 502 in a common gate region defined by the gate sidewall spacers 530. In this configuration, the gate region comprises a single dielectric isolation region 650 which is disposed over the first metal gates 541₁ and 541₂ of the respective first (bottom) transistors 510₁ and 510₂, and which surrounds the second metal gates 542₁ and 542₂ of the respective second (upper) transistors 520₁ and 520₂. Moreover, as schematically shown in FIG. 6, the first metal gates 541₁ and 541₂ are disposed in direct contact with each other to form a merged bottom gate structure, thereby eliminating the need for the second horizontal metallic strap element 572 on the backside (FIG. 5). In addition, the second metal gates 542₁ and 542₂ of the respective second (upper) transistors 520₁ and 520₂ are electrically connected by an extended portion 670 of the second metal gate electrode 548₁ of the second metal gates 542₁, thereby eliminating the need to form the separate first horizontal metallic strap element 570 on the frontside (FIG. 5).

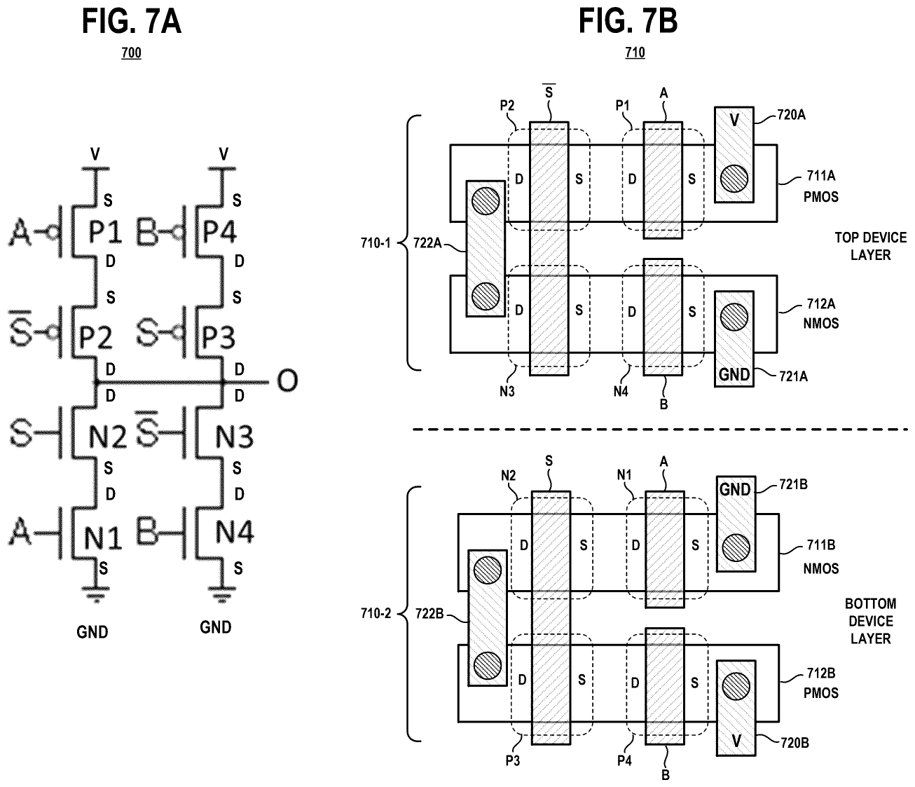

FIGS. 7A and 7B schematically illustrate stacked complementary transistor structures with cross-coupled gate configurations, according to another exemplary embodiment of the disclosure. In particular, FIG. 7A is a schematic circuit diagram of a CMOS circuit 700 comprising four PMOS transistors P1, P2, P3, and P4, and four NMOS transistors N1, N2, N3, and N4, each having respective source(S) and drain (D) regions. In addition, FIG. 7B is a schematic layout 710 of the CMOS circuit 700 showing a schematic plan view of a top device layer 710-1, and a schematic plan view of a bottom device layer 710-2. While the top device layer 710-1 is disposed over the bottom device layer 710-2 (in a vertical Z direction), FIG. 7B shows the top device layer 710-1 and the bottom device layer 710-2 side-by-side for ease of illustration and discussion.

As illustrated by the schematic layout 710 of FIG. 7B, the CMOS circuit 700 comprises four (4) stacked complementary transistor structures with cross-coupled gate configurations, including (i) a first stacked complementary transistor structure comprising P1 disposed over N1, (ii) a second stacked complementary transistor structure comprising P2 disposed over N2, (iii) a third stacked complementary transistor structure comprising N3 disposed over P3, and (iv) a fourth stacked complementary transistor structure comprising N4 disposed over P4. The top device layer 710-1 comprises stacked PMOS nanosheet channels and S/D elements 711A for the transistors P1 and P2, and stacked NMOS nanosheet channels and S/D elements 712A for the transistors N3 and N4. The bottom device layer 710-2 comprises stacked NMOS nanosheet channels and S/D elements 711B for the transistors N1 and N2, and stacked PMOS nanosheet channels and S/D elements 712B for the transistors P3 and P4.

The transistors P1 and N1 of the first stacked complementary transistor structure (P1 disposed over N1) comprise a shared gate structure (denoted A), and the transistors N4 and P4 of the fourth stacked complementary transistor structure (N4 disposed over P4) comprise a shared gate structure (denoted B). The shared gate structures A and B can be implemented using any of the exemplary shared gate configurations of stacked complementary transistor structures (e.g., FIGS. 1A and 2) as discussed herein. In addition, the transistors P2 and N2 of the second stacked complementary transistor structure (P2 disposed over N2) comprise a split gate structure, and the transistors N3 and P3 of the third stacked complementary transistor structure (N3 disposed over P3) comprise a split gate structure. With the split gate structure, an isolated gate element (denoted S) is formed to connect the isolated gates of the transistors P2 and N2 (as shown in FIG. 7B). In addition, with the split gate structure, an isolated gate element (denoted S) is formed to connect the isolated gates of the transistors N2 and P3 (as shown in FIG. 7B).

As further shown in FIG. 7B, the source(S) elements of the transistors P1 and P4 are coupled to power distribution lines 720A and 720B which distribute supply voltage V. In addition, the source(S) elements of the transistors N1 and N4 are coupled to ground (GND) lines 721A and 721B. Moreover, the drain (D) elements of the transistors P2 and N3 in the top device layer 710-1 are commonly connected by a MOL contact/line 722A, and the drain (D) elements of the transistors N2 and P3 in the bottom device layer 710-2 are commonly connected by a MOL contact/line 722B. The MOL contacts/lines 722A and 722B are commonly connected to provide an output port (denoted O) of the CMOS circuit 700 as shown in FIG. 7A.

Conventional fabrication methods for forming dual work function metals typically involve forming a first layer of work function metal to encapsulate the channel layers of the stacked transistors, followed by a metal recess process to remove the first layer of work function metal from the upper transistor, and then forming a second layer of work function metal to encapsulate the channel layers of the upper transistor. However, such conventional methods are problematic in that it can be difficult to control the metal recess process to ensure that a sufficient amount of the first layer of work function metal is removed to thereby form the second layer of work function metal for the upper transistor, without removing too much of the first layer of work function metal, which could lead to degraded performance of bottom transistor. In this regard, exemplary fabrication techniques are provided that allow the dual work function metal layers to be precisely fabricated for the upper and lower transistor devices from the front side in monolithic integration using lithographic patterning methods, while eliminating the need to perform partial work function metal recess steps which, as noted above, are problematic.

FIGS. 8A-8M schematically illustrate a method for fabricating a semiconductor integrated circuit device comprising a stacked complementary transistor structure, according to an embodiment of the disclosure. In particular, FIGS. 8A-8M schematically illustrate a method for fabricating the semiconductor integrated circuit device 100 of FIGS. 1A and 1B. To begin, FIG. 8A is a schematic cross-sectional side view (Y-Z plane) of an intermediate structure of the semiconductor integrated circuit device 100 which comprises a dummy gate 800 (e.g., a polysilicon gate) that is to be replaced with the metal gate 140 by performing an exemplary replacement metal gate (RMG) process. The dummy gate 800 comprises a conformal oxide layer 802 and a dummy gate electrode layer 804 which is formed of a sacrificial material such as polysilicon or amorphous silicon material. In addition, the gate structure shown in FIG. 8A further comprises a gate capping layer 806 (or hard mask layer) which is disposed on the dummy gate electrode layer 804. The gate capping layer 806 has a footprint area which corresponds to and defines the footprint area of the dummy gate electrode layer 804.

The intermediate structure of the semiconductor integrated circuit device 100 as shown in FIG. 8A further comprises a patterned stack of epitaxial semiconductor layers 810 which comprise a first stack of epitaxial semiconductor layers 810-1, a second stack of epitaxial semiconductor layers 810-2, and an MDI layer 125 disposed between the first and second stacks of epitaxial semiconductor layers 810-1 and 810-2. The first stack of epitaxial semiconductor layers 810-1 comprises a stack of alternating epitaxial semiconductor channel and sacrificial layers, including the channel layers 111 and 112 of the first transistor 110, and sacrificial layers 111s, 112s, and 113s. The sacrificial layer 111s is disposed between the substrate 102 and the channel layer 111, the sacrificial layer 112s is disposed between the channel layers 111 and 112, and the sacrificial layer 113s is disposed between the channel layer 112 and the MDI layer 125. Similarly, the second stack of epitaxial semiconductor layers 810-2 comprises a stack of alternating epitaxial semiconductor channel and sacrificial layers, including the channel layers 121, 122, and 123 of the second transistor 120, and sacrificial layers 121s, 122s, and 123s. The sacrificial layer 121s is disposed between the MDI layer 125 and the channel layer 121, the sacrificial layer 122s is disposed between the channel layers 121 and 122, and the sacrificial layer 123s is disposed between the channel layers 122 and 123.

As is known in the art, an epitaxial semiconductor material is a single-crystal (or monocrystalline) semiconductor material that is grown using an epitaxy process. In some embodiments, the epitaxial semiconductor layers of first and second stacks of epitaxial semiconductor layers 810-1 and 810-2 comprise single-crystalline semiconductor materials, which are epitaxially grown using known methods such as chemical vapor deposition (CVD), metal-organic chemical vapor deposition (MOCVD), low pressure chemical vapor deposition (LPCVD), molecular beam epitaxy (MBE), vapor-phase epitaxy (VPE), liquid-phase epitaxy (LPE), metal organic molecular beam epitaxy (MOMBE), rapid thermal chemical vapor deposition (RTCVD), low-energy plasma deposition (LEPD), ultra-high vacuum chemical vapor deposition (UHVCVD), atmospheric pressure chemical vapor deposition (APCVD), or other known epitaxial growth techniques which are suitable for the given process flow.

In some embodiments, the channel layers 111, 112, 121, 122, and 123 of the first and second transistors 110 and 120 are formed of a first type of epitaxial semiconductor material, while the sacrificial layers 111s, 112s, 113s, 121s, 122s, and 123s are formed of a second type of epitaxial semiconductor material, which can be etched selective to the first type of epitaxial semiconductor material to thereby “release” the channel layers 111, 112, 121, 122, and 123, in a subsequent stage of fabrication. For example, in some embodiments, the channel layers 111, 112, 121, 122, and 123 of the first and second transistors 110 and 120 are formed of epitaxial (single-crystalline) silicon (or mono-Si), while the sacrificial layers 111s, 112s, 113s, 121s, 122s, and 123s are formed of an epitaxial (single-crystalline) silicon-germanium (SiGe) alloy. This allows the epitaxial SiGe material of the sacrificial layers 111s, 112s, 113s, 121s, 122s, and 123s to be etched selective to the epitaxial Si material of the channel layers 111, 112, 121, 122, and 123 in a subsequent process step to “release” the channel layers 111, 112, 121, 122, and 123 of the first and second transistors 110 and 120. In other embodiments, the channel layers 111, 112, 121, 122, and 123 of the first and second transistors 110 and 120 can be formed of an epitaxial SiGe material with a desired Ge concentration (optimized for device performance), while the sacrificial layers 111s, 112s, 113s, 121s, 122s, and 123s are formed of, e.g., epitaxial silicon.

It is to be noted that the intermediate structure shown in FIG. 8A can be fabricated using suitable semiconductor fabrication process modules and materials. The substrate 102 may comprise one or more of various types of semiconductor substrate structures and materials. For example, in some embodiments, the substrate 102 comprises a bulk semiconductor substrate (e.g., wafer) that is formed of monocrystalline semiconductor material including, but not limited to, silicon, germanium, or other types of semiconductor substrate materials that are commonly used in bulk semiconductor fabrication processes such as a SiGe alloy, silicon germanium carbide (SiGeC), silicon carbide (SIC), III-V semiconductor materials such as gallium arsenide (GaAs), gallium nitride (GaN), etc. In other embodiments, the substrate 102 may be an active semiconductor layer of an SOI (silicon-on-insulator) substrate, GeOI (germanium-on-insulator) substrate, or another type of semiconductor-on-insulator substrate.

At an early stage of fabrication, the patterned stack of epitaxial semiconductor layers 810 is formed on the substrate 102 by sequentially depositing layers of epitaxial material over the substrate 102, and then performing one or more lithographic patterning processes to pattern the deposited layers of epitaxial material (via dry etch processes such as reactive ion etch (RIE) processes) to thereby form the patterned stack of epitaxial semiconductor layers 810. In addition, the substrate 102 is lithographically patterned to form an STI trench around the patterned stack of epitaxial semiconductor layers 810, and the STI trench is filled with one or more layers of insulating material to form the STI layer 104. In some embodiments, the patterning process results in the bottom portion of the patterned stack of epitaxial semiconductor layers 810 having a width (in the Y direction) that defines the gate width W_{G1} of the first transistor 110, and an initial stack length L_{S} (in the X direction, as shown in FIG. 1B) which defines an overall target length L of the gate structure plus source/drains (S/D) regions of the substrate 102 on opposing sides of the gate structure.

A next stage of the fabrication process comprises constructing the dummy gate 800 which is surrounded by the gate sidewall spacer 130. In some embodiments, the dummy gate 800 is formed by a process which comprises (i) depositing a thin conformal oxide layer (e.g., conformal layer of silicon dioxide) over the entire surface of the semiconductor substrate, (ii) depositing a blanket layer of polysilicon (or alternatively, amorphous silicon) over the conformal oxide layer, (iii) planarizing the blanket layer of polysilicon using, e.g., a chemical mechanical polishing (CMP) process, and (iv) lithographically patterning the planarized layer of polysilicon and the conformal oxide layer to form the conformal oxide layer 802 and the dummy gate electrode layer 804 of the dummy gate 800.

In some embodiments, the lithographic patterning process to form the dummy gate 800 comprises forming a hard mask layer on the planarized surface of the polysilicon layer by depositing a layer of dielectric material or multiple layers of dielectric materials including, but not limited to such as silicon nitride (SiN), silicon boron carbide nitride (SiBCN), silicon oxycarbonitride (SiOCN), etc., and patterning the hard mask layer to form the gate capping layer 806 which defines a footprint image of dummy gate 800 (and thus the subsequently formed metal gate 140). For example, in some embodiments, the gate capping layer 806 has a footprint arca defined by a width W in the Y-direction (FIG. 1A), and a length of LG in the X-direction (FIG. 1B). The gate capping layer 806 is then utilized as an etch hard mask to anisotropically etch (e.g., RIE) the sacrificial polysilicon and oxide layers down to the upper surface of the substrate 102 to thereby form the dummy gate 800 which covers the patterned stack of epitaxial semiconductor layers 810, except for portions of the patterned stack of epitaxial semiconductor layers 810 that extend from the dummy gate 800 in the X-direction (given that the initial stack length Ls of the patterned stack of epitaxial semiconductor layers 810 in the X-direction is initially longer than the length LG of the dummy gate 800 in the X-direction.

The gate sidewall spacer 130 is then formed by depositing a conformal layer of dielectric material over the entire surface of the semiconductor structure. The conformal layer of dielectric material can be formed of SiN, SiBCN, SiCON, or any other type of low-k dielectric material that is commonly used to form insulating gate sidewall spacers of FET devices (e.g., a low-k dielectric material having a k of less than 5, wherein k is the relative dielectric constant), and deposited using known techniques such as atomic layer deposition (ALD), chemical vapor deposition (CVD), or physical vapor deposition (PVD). The conformal layer of dielectric material is then patterned by performing an anisotropic dry etch process (e.g., RIE process), to selectively etch down the conformal layer of dielectric material in a vertical direction (Z-direction), which results in the formation of the gate sidewall spacer 130 that surrounds the dummy gate 800 and defines the footprint region of the metal gate 140. This etch process is performed selective to the semiconductor materials of the patterned stack of epitaxial semiconductor layers 810 and the STI layer 104.

In some embodiments, after forming the gate sidewall spacer 130, an anisotropic dry etch process (e.g., RIE) is performed to etch down the exposed portions of the patterned stack of epitaxial semiconductor layers 810 which extend past the gate sidewall spacer 130 in the X-direction. This etch process serves to reduce the length of the patterned stack of epitaxial semiconductor layers 810 from the initial stack length Ls to the length L, where the length ends of the channel layers 111, 112, 121, 122, and 123 and the sacrificial layers 111s, 112s, 113s, 121s, 122s, and 123s of the patterned stack of epitaxial semiconductor layers 810 are essentially coplanar with the outer vertical sidewall surfaces of the gate sidewall spacer 130 in the X-direction.

A next step in the fabrication process comprises laterally recessing (in the X-direction) exposed sidewall surfaces of the sacrificial layers 111s, 112s, 113s, 121s, 122s, and 123s of the patterned stack of epitaxial semiconductor layers 810 to form recesses at a depth which corresponds to a thickness of the gate sidewall spacer 130, and then filling such recesses with dielectric material to form the embedded gate sidewall spacers 132 as shown in FIG. 1B. In some embodiments, the lateral etch process can be performed using an isotropic wet etch process with an etch solution that is suitable to etch the semiconductor material (e.g., SiGe) of the sacrificial layers 111s, 112s, 113s, 121s, 122s, and 123s selective to the semiconductor material (e.g., Si) of the channel layers 111, 112, 121, 122, and 123 of the first and second transistors 110 and 120.

The gate sidewall spacers 132 are then formed within the recesses by a process which comprises depositing a conformal layer of dielectric material until the recesses are filled with dielectric material, and performing an etch back process to remove the excess dielectric material from the gate structure and the substrate. The gate sidewall spacers 132 can be formed of the same or similar dielectric material as the gate sidewall spacer 130 (e.g., SiN, SiBCN, SiCO, SiBCN, SiCON), or any other type of low-k dielectric material. The dielectric material can be deposited using a highly conformal deposition process, such as ALD, to ensure that the recesses are sufficiently filled with dielectric material. The conformal layer of dielectric material can be etched back using an isotropic (wet or dry) etch process to remove the excess dielectric material, while leaving the dielectric material in the recesses to form the gate sidewall spacers 132. The wet etch process may include, but is not limited to, buffered hydrofluoric acid (BHF), diluted hydrofluoric acid (DHF), hydrofluoric nitric acid (HNA), phosphoric acid, HF diluted by ethylene glycol (HFEG), hydrochloric acid (HCl), or any combination thereof.

A next step in the fabrication process comprises forming the first and second source/drain elements 118-1 and 118-2 of the first transistor 110, followed by forming the first and second source/drain elements 128-1 and 128-2 of the second transistor 120, by utilizing epitaxial growth techniques. The types of epitaxial semiconductor materials that are utilized to form the first and second source/drain elements 118-1 and 118-2 of the first transistor 110 will depend on whether the first transistor 110 is a N-type MOSFET or P-type MOSFET. For example, in an exemplary embodiment where the first transistor 110 is a N-type MOSFET and the second transistor 120 is a P-type MOSFET, and where the channel layers 111, 112, 121, 122, and 123 are formed of epitaxial Si, (i) the first and second source/drain elements 118-1 and 118-2 of the first transistor 110 can be formed of carbon-doped silicon (Si:C) epitaxial material, or phosphorus-doped silicon (Si:P) epitaxial material, or other suitable epitaxial materials for N-type MOSFET devices, and (ii) the first and second source/drain elements 128-1 and 128-2 of the second transistor 120 can be formed of an epitaxial SiGe material (with a relatively high Ge concentration), or a boron-doped SiGe (B: SiGe) epitaxial material, or other suitable epitaxial materials for P-type MOSFET devices.

It is to be noted that the source/drain elements can be formed using various techniques known to those of ordinary skill in the art. For example, in some embodiments, the first and second source/drain elements 118-1 and 118-2 of the first transistor 110 can be epitaxially grown from the bottom up starting on, e.g., the exposed <100> crystalline silicon surface in the S/D regions of the substrate 102 as a seed surface. With this process, the epitaxial process is configured so that a growth rate of the epitaxial material on the <100> crystalline plane surface of the substrate is greater than a growth rate of the epitaxial material on the exposed side surfaces of the channel layers 111, 112, 121, 122, and 123 of the first and second transistors 110 and 120, which have a <110> crystalline plane orientation. In this process, the substrate surface provides a <100>semiconductor surface to seed the growth of the epitaxial material which forms the first and second source/drain elements 118-1 and 118-2, wherein the deposited epitaxial semiconductor material takes on the same lattice structure and orientation of the crystalline seed surface.

In other embodiments, the first and second source/drain elements 118-1 and 118-2 of the first transistor 110 can be epitaxially grown starting on the exposed sidewall surfaces of the channel layers 111 and 112 which provide the surface area to seed the epitaxial growth of the first and second source/drain elements 118-1 and 118-2. In some embodiments, the epitaxial growth of the semiconductor material is performed so that the epitaxial material merges (in the Z-direction) to form the first and second source/drain elements 118-1 and 118-2 of the first transistor 110. With this process, the exposed sidewall surfaces of the channel layers 121, 122, and 123 of the second transistor 120 are covered with insulating/dielectric material using known techniques to prevent epitaxial growth on the exposed sidewall surfaces of the channel layers 121, 122, and 123 of the second transistor 120 during the epitaxial process to grow the first and second source/drain elements 118-1 and 118-2 of the first transistor 110.

Next, the first and second source/drain elements 128-1 and 128-2 of the second transistor 120 can formed by epitaxially growing semiconductor material on the exposed sidewall surfaces of the channel layers 121, 122, and 123. In this process, exposed sidewall surfaces of the channel layers 121, 122, and 123 provide a surface area to seed the epitaxial growth of the first and second source/drain elements 128-1 and 128-2. In some embodiments, the epitaxial growth of the semiconductor material is performed so that the epitaxial material merges (in the Z-direction) to form the first and second source/drain elements 128-1 and 128-2 of the second transistor 120.

It is to be noted that prior to forming the first and second source/drain elements 128-1 and 128-2 of the second transistor 120, the first and second source/drain elements 118-1 and 118-2 of the first transistor 110 are covered by insulating material to protect the first and second source/drain elements 118-1 and 118-2 from damage and/or additional growth of epitaxial material during the formation of the first and second source/drain elements 128-1 and 128-2 of the second transistor 120. For example, a conformal dielectric protective liner can be conformally formed on the first and second source/drain elements 118-1 and 118-2 and/or an initial shallow layer of the pre-metallization dielectric layer 106 can be formed to cover the first and second source/drain elements 118-1 and 118-2 during the during the epitaxial process to grow the first and second source/drain elements 128-1 and 128-2 of the second transistor 120.

Following the formation of the first and second source/drain elements 128-1 and 128-2 of the second transistor 120, the process flow continues with forming the pre-metallization dielectric layer 106, prior to commencing the replacement metal gate process. In some embodiments, the pre-metallization dielectric layer 106 is formed by depositing a blanket layer of dielectric/insulating material over the semiconductor structure and planarizing the layer of dielectric/insulating material down to the gate capping layer 806. The pre-metallization dielectric layer 106 may comprise any suitable insulating/dielectric material that is commonly utilized in semiconductor process technologies including, but not limited to, silicon oxide, silicon nitride, silicon oxynitride, SiCOH, SiCH, SiCNH, or other types of silicon-based low-k dielectrics (e.g., k less than about 4.0), porous dielectrics, known ULK (ultra-low-k) dielectric materials (with k less than about 2.5), or any suitable combination of those materials. The dielectric/insulating material of the pre-metallization dielectric layer 106 is deposited using known deposition techniques, such as, for example, ALD, CVD, PECVD, PVD, or spin-on deposition. In some embodiments, the layer of dielectric/insulating material is planarized using a standard planarization process such as CMP to remove the overburden dielectric/insulating down to the upper surface of the gate capping layer 806. In some embodiments, a conformal layer of dielectric material (e.g., SiN) is deposited prior to depositing the insulating material of pre-metallization dielectric layer 106 to form a protective liner layer which covers source/drain elements of the first and second transistors 110 and 120.

Following the formation of the pre-metallization dielectric layer 106, the exemplary replacement metal gate process is performed to replace the dummy gate 800 with the metal gate 140, using the exemplary process flow schematically illustrated in FIGS. 8B-8M. For example, FIG. 8B is a schematic cross-sectional side view of an intermediate structure of the semiconductor integrated circuit device 100 which is obtained after forming a trench opening 800-1 in the dummy gate 800 to expose the second stack of epitaxial semiconductor layers 810-2 of the patterned stack of epitaxial semiconductor layers 810. In some embodiments, the trench opening 800-1 is formed by a process which comprises (i) lithographically patterning the gate capping layer 806 (or hard mask layer) to form an opening in the gate capping layer 806 which defines an image of the trench opening 800-1, (ii) performing a first etch process to etch the material of the dummy gate electrode layer 804 (e.g., polysilicon material) and form the trench opening 800-1 down to a level of the MDI layer 125, and (iii) performing a second etch process to remove a portion of the conformal oxide layer 802 exposed at the bottom of the trench opening 800-1.

In some embodiments, the first etch process is performed using an anisotropic etch process (e.g., RIE) to etch the material (e.g., polysilicon) of the dummy gate electrode layer 804 selective to, e.g., the conformal oxide layer 802, to thereby protect the second stack of epitaxial semiconductor layers 810-2 when forming the trench opening 800-1. The second etch process comprises an oxide etch process that is performed to etch away the exposed portion of the conformal oxide layer 802 selective to the materials of the dummy gate electrode layer 804 and the second stack of epitaxial semiconductor layers 810-2. In this manner, the trench opening 800-1 can be formed to expose the second stack of epitaxial semiconductor layers 810-2 without damaging the channel layers 121, 122, 123 of the second transistor 120.

Next, FIG. 8C is a schematic cross-sectional side view of an intermediate structure of the semiconductor integrated circuit device 100 which is obtained after filling the trench opening 800-1 with sacrificial dielectric material 820. In some embodiments, the sacrificial dielectric material 820 comprises any dielectric material that is suitable for the given application, such as SiN or another type of dielectric material which has etch selectivity with respect to the materials of the conformal oxide layer 802, the dummy gate electrode layer 804, and other elements. The sacrificial dielectric material 820 is deposited using a suitable deposition process, such as a liquid flowable CVD (FCVD) process which is capable of filling high aspect ratio trenches from the bottom up. After filling the trench opening 800-1 with the sacrificial dielectric material 820, a CMP process can be performed to remove overburden dielectric material and planarize the surface of the intermediate device structure down to the upper surface of the dummy gate electrode layer 804, which results in the removal of the remaining portion of the gate capping layer 806.

Next, FIG. 8D is a schematic cross-sectional side view of an intermediate structure of the semiconductor integrated circuit device 100 which is obtained after removing a remaining portion of the dummy gate 800 to form an open region 800-2 that exposes the underlying first stack of epitaxial semiconductor layers 810-1. In some embodiments, the remaining portion of the dummy gate 800 is removed by a process which comprises (i) performing a first etch process (e.g., poly etch process) to selectively etch away the remaining material of the dummy gate electrode layer 804 (e.g., polysilicon material), and (ii) performing a second etch process (e.g., oxide etch) to selectively etch away a remaining portion of the conformal oxide layer 802 to thereby expose the underlying first stack of epitaxial semiconductor layers 810-1.

The dummy gate electrode layer 804 (e.g., polysilicon layer) is removed using a dry etch or wet etch process with suitable etch chemistries, including ammonium hydroxide (NH₄OH), tetramethylammonium hydroxide (TMAH), or SF6 plasma, which allows the remaining portion of the dummy gate electrode layer 804 to be etched selective to, e.g., the sacrificial dielectric material 820, the conformal oxide layer 802, and other surrounding elements. The oxide etch process is performed to etch away the conformal oxide layer 802 selective to the sacrificial dielectric material 820 and the epitaxial semiconductor materials of the first stack of epitaxial semiconductor layers 810-1.

Next, FIG. 8E is a schematic cross-sectional side view of an intermediate structure of the semiconductor integrated circuit device 100 which is obtained after selectively etching the sacrificial layers 111s, 112s, and 113s of the first stack of epitaxial semiconductor layers 810-1 to release the channel layers 111 and 112 of the first transistor 110. For example, in exemplary embodiments where the sacrificial layers 111s, 112s, and 113s are formed of an epitaxial SiGe material, and the channel layers 111 and 112 are formed of epitaxial Si material, the sacrificial layers 111s, 112s, and 113s can be selectively etched (with high etch selectivity) via an isotropic dry etch process (e.g., a gas phase HCl (hydrochloric acid) etch) or an isotropic wet etch process (e.g., a wet etch solution containing hydrogen peroxide (H₂O₂)) to etch the SiGe material of the sacrificial layers selective to the Si material of the channel layers 111 and 112. A vapor phase HCL gas isotropic etch process provides high etch selectivity when, for example, the channel layers 111 and 112 are formed of epitaxial Si or an epitaxial SiGe with a lower Ge concentration than the epitaxial SiGe material of the sacrificial layers 111s, 112s, and 113s.

Next, FIG. 8F is a schematic cross-sectional side view of an intermediate structure of the semiconductor integrated circuit device 100 which is obtained after forming high-k gate dielectric layers 141 on exposed surfaces of the channel layers 111 and 112 of the first transistor 110. In some embodiments, a process for forming the high-k gate dielectric layers 141 comprises (i) performing a channel pre-clean process to clean the exposed epitaxial silicon surfaces of the channel layers 111 and 112, (ii) forming ultra-thin interfacial layers on the exposed epitaxial silicon surfaces of the channel layers 111 and 112, and (iii) depositing a high-k dielectric material to form the high-k gate dielectric layers 141.

In some embodiments, the ultra-thin interfacial layers are formed by performing an oxidation process to grow ultra-thin interfacial silicon oxide layers on the exposed surfaces of the channel layers 111 and 112. For example, in some embodiments, the interfacial silicon oxide layers (e.g., silicon dioxide) are formed using a chemical oxidation process in an ozonated deionized water comprising ozone, and a suitable oxidation temperature, ozone concentration in the deionized water, and chemical oxidation process time to form thin interfacial silicon oxide layers (e.g., silicon dioxide layers). In some embodiments, a low-temperature SiO₂ interfacial layer can be formed using a rapid thermal oxidation (RTO) process. In other embodiments, the interfacial silicon oxide layers can be thin layers of silicon oxynitride (SiON) formed on the exposed surfaces of the channel layers 111 and 112. For example, in embodiments where the first transistor 110 comprises an N-type MOSFET device, SiON interfacial layers can be formed on the exposed surfaces of channel layers 111 and 112 (e.g., epitaxial silicon channel layers. In some embodiments, the ultra-thin interfacial layers of silicon oxide are formed with a thickness in a range of about 1 angstrom to about 10 angstroms (i.e., about 0.1 nm to about 1 nm).

In some embodiments, the high-k gate dielectric layers 141 are formed by depositing one or more conformal layers of high-k dielectric material over the exposed surfaces of the semiconductor structure to conformally cover the surfaces of the channel layers 111 and 112. Moreover, as schematically illustrated in FIG. 8F, the process of forming the high-k gate dielectric layers 141 on the channel layers 111 and 112 also results in the formation of the residual dielectric layer 141A on the exposed surfaces of the sacrificial dielectric material 820 and the MDI layer 125, as well as on the exposed bottom and sidewall surfaces within the open region 800-2.

In some embodiments, the high-k gate dielectric layers 141 are preferably formed of a high-k dielectric material having a dielectric constant of about 3.9 or greater. For example, the gate dielectric material can include but is not limited to metal oxides such as hafnium oxide, hafnium silicon oxide, hafnium silicon oxynitride, hafnium zirconium oxide, and nitride films thereof. In other embodiments, the high-k gate dielectric may comprise lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric material may further include dopants such as lanthanum, aluminum. In some embodiments, the conformal high-k gate dielectric layers 141 are formed with a thickness in a range of about 0.5 nm to about 2.0 nm, which will vary depending on the target application. The conformal layer of high-k dielectric material is deposited using known methods such as ALD, for example, which allows for high conformality of the gate dielectric material.

Next, FIG. 8G is a schematic cross-sectional side view of an intermediate structure of the semiconductor integrated circuit device 100 which is obtained after forming the first metal gate electrode 142 of the first transistor 110. As noted above, in some embodiments, the first metal gate electrode 142 comprises a layer of a first work function metal which encapsulates the channel layers 111 and 112 of the first transistor 110, wherein the first metal gate electrode 142 can be formed entirely of the first work function metal. In other embodiments, the first metal gate electrode 142 is formed by sequentially performing multiple metal deposition processes to initially deposit one or more layers of work function metal to form the first work function metal layer which encapsulates the channel layers 111 and 112 of the first transistor 110, and then deposit a low-resistance metallic material (e.g., tungsten, ruthenium, cobalt, copper, aluminum, etc.) on the first work function metal layer to fill a remaining portion of the open region 800-2 with metallic material to form the first metal gate electrode 142. A CMP process is then performed to remove the overburden material (e.g., gate dielectric material and metal gate electrode material), and planarize the upper surface of the device down to the pre-metallization dielectric layer 106, resulting in the intermediate device structure shown in FIG. 8G.

In some embodiments, the first work function metal layer for the first transistor 110 comprises one or more layers of work function metal that are selected to achieve desired electrical properties of the metal gate for the given device type of the first transistor 110. For example, in some embodiments where the first transistor 110 is an N-type MOSFET, the first work function metal layer is engineered to ensure that the channel layers 111 and 112 of the first transistor 110 effectively operate as an N-doped channel. In some embodiments, the first work function metal layer is formed of titanium nitride (TiN). In some embodiments, the first work function metal layer comprises multiple layers of work function metals including, for example, two layers of TiN with a layer of titanium aluminum carbide (TiAlC) disposed between the two layers of TiN (e.g., a trilayer stack of TiN/TiAlC/TiN work function metals). It is to be noted that other types of work function metals or metal alloys can be utilized to form the first work function metal layer, which are suitable for the given type (e.g., N-type) of the first transistor 110.

It is to be noted that the exemplary fabrication process allows the high-k gate dielectric and gate metallization of the first and second transistors 110 and 120 to be separately formed and optimized for the target device type (e.g., N-type or P-type). In particular, at the exemplary stage of fabrication shown in FIG. 8G, the high-k gate dielectric and gate metallization of the first transistor 110 are initially formed, while the high-k gate dielectric and gate metallization of the second transistor 120 are separately formed in subsequent stages of fabrication (e.g., FIGS. 8H through 8K). In this regard, the types of materials that are used to form the interfacial layer, the high-k gate dielectric layer, and the work function metal for the first transistor 110 can be optimized for the target device type (e.g., N-type) of the first transistor 110 (e.g., the interfacial layer for an NMOS transistor can be formed of SiON). In addition to customizing the types of materials, the process allows the thickness of the high-k gate dielectric to be optimized for the given device type. For example, for an N-type nanosheet MOSFET, the high-k gate dielectric layer can be made thinner, as compared to the high-k gate dielectric layer for a P-type nanosheet MOSFET, for a given equivalent oxide thickness (EOT).

Next, FIG. 8H is a schematic cross-sectional side view of an intermediate structure of the semiconductor integrated circuit device 100 which is obtained after removing the sacrificial dielectric material 820 to form a trench opening 820-1 which exposes the underlying second stack of epitaxial semiconductor layers 810-2. The sacrificial dielectric material 820 is removed using any suitable etch process and etch chemistry that is configured to etch away the sacrificial dielectric material 820 selective to the materials of, e.g., the residual dielectric layer 141A, the underlying second stack of epitaxial semiconductor layers 810-2, and the MDI layer 125.

Next, FIG. 81 is a schematic cross-sectional side view of an intermediate structure of the semiconductor integrated circuit device 100 which is obtained after selectively etching away the sacrificial layers 121s, 122s, and 123s of the second stack of epitaxial semiconductor layers 810-2 to release the channel layers 121, 122, and 123 of the second transistor 120. It is to be noted that the channel layers 121, 122, and 123 of the second transistor 120 can be released using the same or similar processes as discussed above (in conjunction with FIG. 8E) for releasing the channel layers 111 and 112 of the first transistor 110, the details of which need not be repeated.

Next, FIG. 8J is a schematic cross-sectional side view of an intermediate structure of the semiconductor integrated circuit device 100 which is obtained after forming interfacial layers and high-k gate dielectric layers 143 on exposed surfaces of the channel layers 121, 122, and 123 of the second transistor 120. Moreover, as schematically illustrated in FIG. 8J, the process of forming the high-k gate dielectric layers 143 on the channel layers 121, 122, and 123 also results in the formation of the residual dielectric layer 143A on the exposed surfaces of residual dielectric layer 141A and the MDI layer 125.

It is to be noted that the interfacial layers and the high-k gate dielectric layers 143 can be formed on the channel layers 121, 122, and 123 of the second transistor 120 using the same or similar processes as discussed above (in conjunction with FIG. 8F) for forming the interfacial layers and the high-k gate dielectric layers 141 on the channel layers 111 and 112 of the first transistor 110, the details of which need not be repeated. However, as noted above, the types of materials that are used to form the interfacial layers and the high-k gate dielectric layers 143 on the channel layers 121, 122, and 123 for the second transistor 120 can be selected to optimize the device performance for the given device type (e.g., P-type) of the second transistor 120. For example, in some embodiments, the interfacial layers of the second transistor 120 (e.g., P-type) can be formed of formed of SiO₂, while the interfacial layers of the first transistor 110 (e.g., N-type) can be formed of SiON.

Next, FIG. 8K is a schematic cross-sectional side view of an intermediate structure of the semiconductor integrated circuit device 100 which is obtained after forming the second metal gate electrode 144 of the second transistor 120. As noted above, in some embodiments, the second metal gate electrode 144 comprises a layer of a second work function metal which encapsulates the channel layers 121, 122, and 123 of the second transistor 120, wherein the second metal gate electrode 144 can be formed entirely of the second work function metal. In some embodiments, the second work function metal layer for the second transistor 120 comprises one or more layers of work function metal that are selected to achieve desired electrical properties of the metal gate for the given device type of the second transistor 120. For example, in some embodiments where the second transistor 120 is a P-type MOSFET, the second work function metal layer is engineered to ensure that the channel layers 121, 122, and 123 of the second transistor 120 effectively operate as a P-doped channel. In some embodiments, the second work function metal layer is formed of titanium nitride (TiN).

In other embodiments, the second metal gate electrode 144 is formed by sequentially performing multiple metal deposition processes to initially deposit one or more layers of work function metal to form the second work function metal layer which encapsulates the channel layers 121, 122, and 123 of the second transistor 120, and then deposit a low-resistance metallic material (e.g., tungsten, ruthenium, cobalt, copper, aluminum, etc.) on the second work function metal layer to fill a remaining portion of the trench opening 820-1 with metallic material to form the second metal gate electrode 144. A CMP process is then performed to remove the overburden material (e.g., gate dielectric material and metal gate electrode material), and planarize the upper surface of the device down to the pre-metallization dielectric layer 106, resulting in the intermediate device structure shown in FIG. 8K.

As noted above, with the intermediate device structure shown in FIG. 8K, the first metal gate electrode 142 and the second metal gate electrode 144 are electrically isolated by the MDI layer 125 and the residual dielectric layers 141A and 143A, and need to be electrically connected to form a shared metal gate structure for the first and second transistors 110 and 120. In some embodiments, a shared metal gate structure is achieved by forming the metallic strap 146 (as shown in FIGS. 1A and 1B) which provides an electrical connection between the first metal gate electrode 142 and the second metal gate electrode 144.

For example, FIG. 8L is a schematic cross-sectional side view of an intermediate structure of the semiconductor integrated circuit device 100 which is obtained after recessing the first metal gate electrode 142 and the second metal gate electrode 144 to a desired depth d to form a recessed cavity 830. A metal deposition process is then performed to fill the recessed cavity 830 with a low-resistance metallic material such as tungsten, followed by a CMP process to remove the overburden metallic material down to the upper surface of the pre-metallization dielectric layer 106, resulting in the formation of the metallic strap 146 of the semiconductor integrated circuit device 100 of FIGS. 1A and 1B. The metallic strap 146 forms a low-resistance electrical connection between the first metal gate electrode 142 and the second metal gate electrode 144, thereby resulting in the metal gate 140 for the first and second transistors 110 and 120, where the metal gate 140 comprises a shared gate structure for the first and second transistors 110 and 120.

In other embodiments, a shared metal gate structure is achieved by forming the metallic plug 246 (shown in FIG. 2) to provide an electrical connection between the first metal gate electrode 142 and the second metal gate electrode 144. For example, starting with the intermediate device structure shown in FIG. 8K, in an alternate embodiment of a fabrication process, FIG. 8M is a schematic cross-sectional side view of an intermediate structure of the semiconductor integrated circuit device which is obtained after recessing patterning an open trench 831 in portions of the first metal gate electrode 142 and the second metal gate electrode 144. A metal deposition process is then performed to fill the open trench 831 with a low-resistance metallic material such as tungsten, followed by a CMP process to remove the overburden metallic material down to the upper surface of the pre-metallization dielectric layer 106, resulting in the formation of the metallic plug 246 of the semiconductor integrated circuit device 200 of FIG. 2. The metallic plug 246 forms a low-resistance electrical connection between the first metal gate electrode 142 and the second metal gate electrode 144, thereby resulting in the metal gate 240 (shared metal gate structure) for the first and second transistors 110 and 120 of the semiconductor integrated circuit device 200 shown in FIG. 2.

It is to be noted that the exemplary semiconductor fabrication process as shown and described above in conjunction with FIGS. 8A-8K can be utilized to fabricate the exemplary semiconductor integrated circuit device 300 of FIG. 3. In particular, starting with the intermediate device structure shown in FIG. 8K, the ILD layer 350 is formed by depositing a layer of dielectric material over the planarized surface of the device structure, and then patterning the ILD layer 350 to form trench and/or via openings in the ILD layer 350. The trench and/or via openings in the ILD layer 350 are then filled with metallic material to form the gate electrode contacts 360 and 362. The ILD layer 350 and gate electrode contacts 360 and 362 can be formed using fabrication techniques and materials, which are well-known to those of ordinary skill in the art.

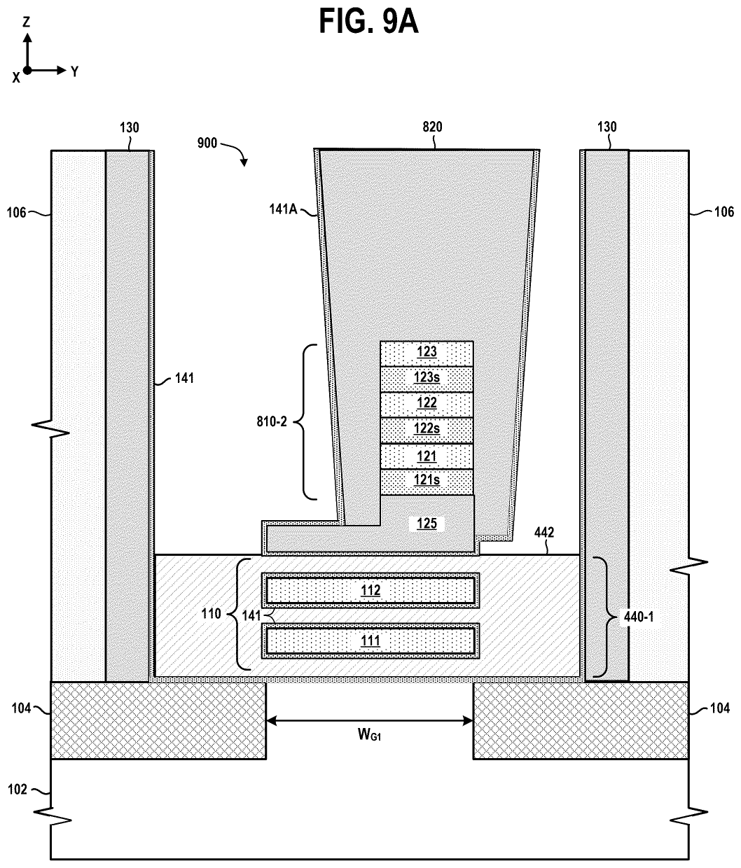

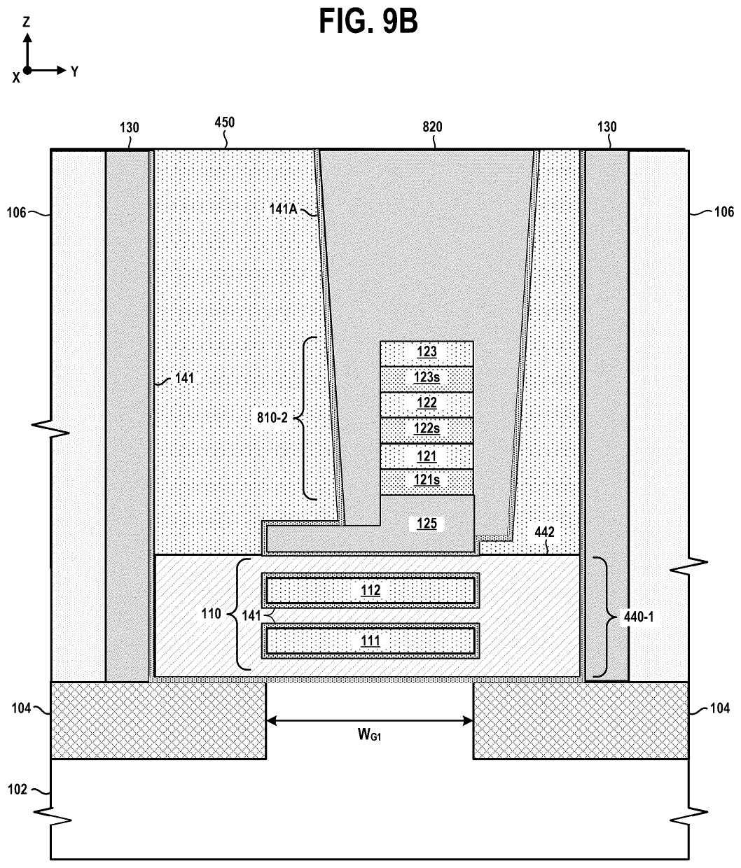

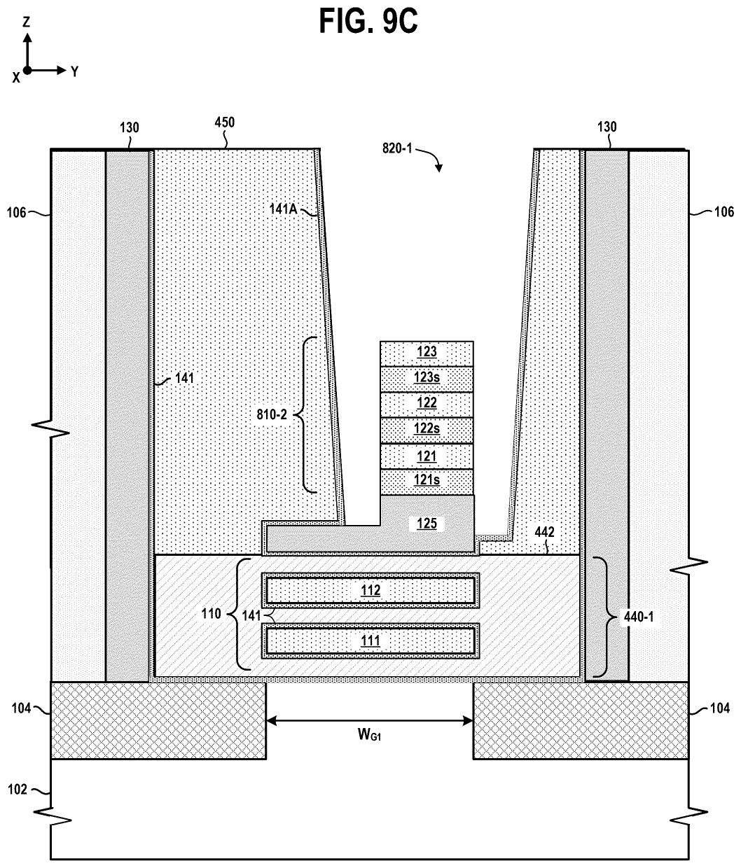

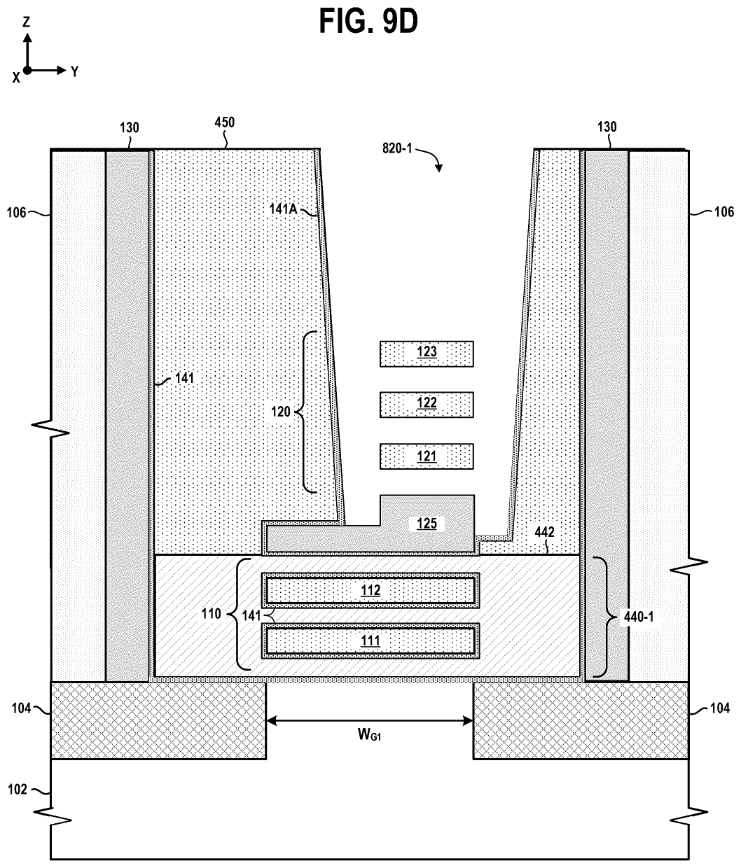

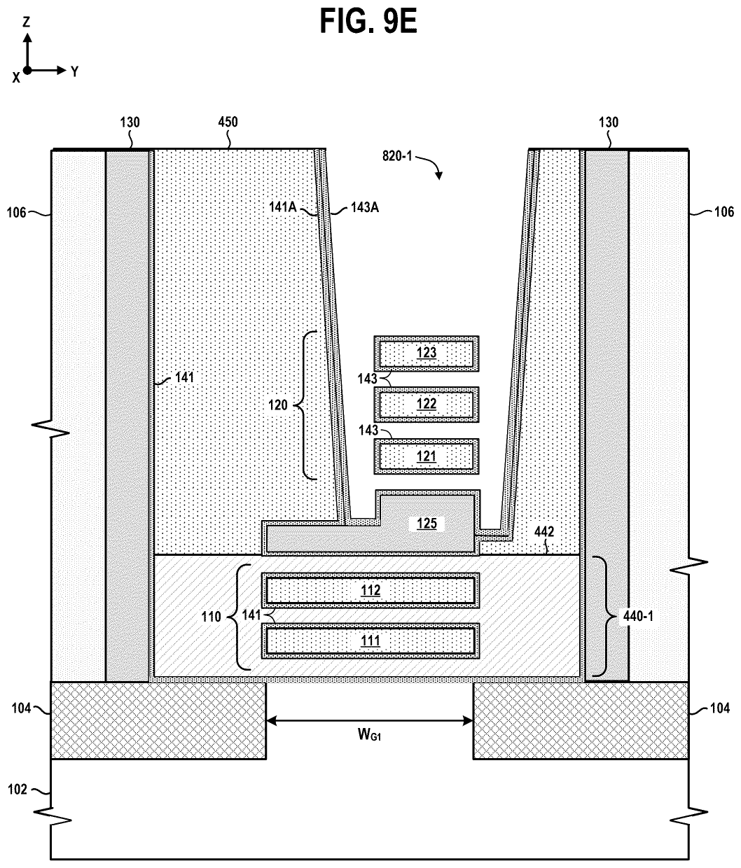

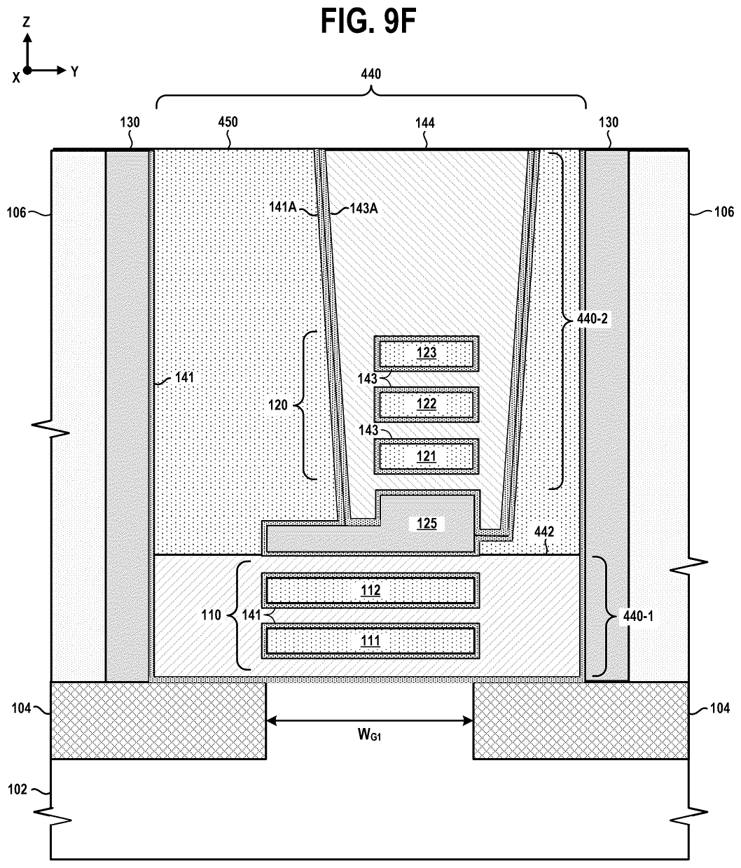

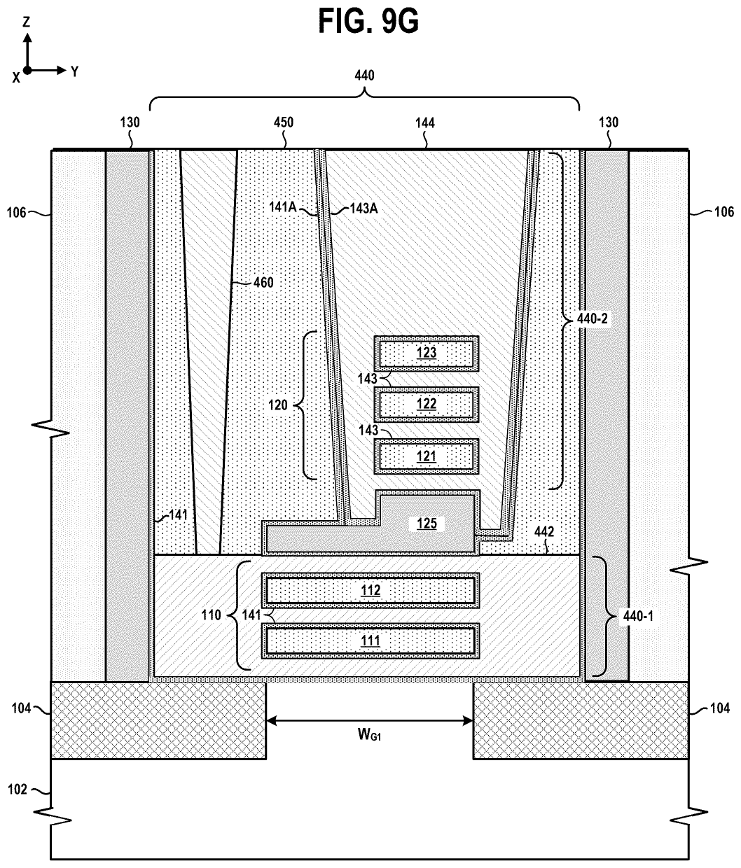

Next, FIGS. 9A-9G schematically illustrate a method for fabricating a semiconductor integrated circuit device comprising a stacked complementary transistor structure, according to another embodiment of the disclosure. In particular, FIGS. 9A-9G schematically illustrate a method for fabricating the semiconductor integrated circuit device 400 of FIG. 4 which comprises a metal gate (e.g., the metal gate 440) having an exemplary split gate structure. In some embodiments, a fabrication process to construct the semiconductor integrated circuit device 400 implements the fabrication process flow shown and discussed above in conjunction with FIGS. 8A-8G, the details of which need not be repeated. In this regard, the process flow of FIGS. 9A-9G starts with the exemplary intermediate device structure shown in FIG. 8G in which the gate metallization for the first gate electrode (e.g., first metal gate electrode 142 as shown in FIG. 8G) of the first transistor 110 is initially deposited to fill the open region 800-2.

Next, FIG. 9A is a schematic cross-sectional side view of an intermediate structure of the semiconductor integrated circuit device 400 which is obtained after recessing the initially deposited gate metallization to form the buried first metal gate electrode 442 which encapsulates the channel layers 111 and 112 of the first transistor 110. In some embodiments, the gate metal recess process is performed to recess the initially deposited gate metallization to a level of the MDI layer 125 (e.g., to a level that is substantially coplanar with a bottom surface of the MDI layer 125). The gate metal recess can be performed using any suitable directional metal etch process and etch chemistry that is configured to selectively etch down the gate metallization material. As schematically shown in FIG. 9A, the gate metal recess process results in forming the first metal gate 440-1 of the first transistor 110 (which comprises the high-k gate dielectric layers 141 and the buried first metal gate electrode 442), and an open region 900 within the gate region above the first metal gate 440-1, which surrounds the sacrificial dielectric material 820.

Next, FIG. 9B is a schematic cross-sectional side view of an intermediate structure of the semiconductor integrated circuit device 400 which is obtained after filling the open region 900 with dielectric material to form the dielectric isolation layer 450. In some embodiments, the dielectric isolation layer 450 is formed by depositing a layer of dielectric material to fill the open region 900, followed by a CMP process to remove the overburden dielectric material and planarize the surface of the device structure down to the pre-metallization dielectric layer 106. In some embodiments, the dielectric isolation layer 450 is formed of a dielectric material which is the same or similar to the dielectric material of the gate sidewall spacer 130 or the MDI layer 125. As schematically shown in FIG. 9B, the dielectric isolation layer 450 covers the first metal gate 440-1 and surrounds the sacrificial dielectric material 820.

Next, FIG. 9C is a schematic cross-sectional side view of an intermediate structure of the semiconductor integrated circuit device 400 which is obtained after removing the sacrificial dielectric material 820 to form a trench opening 820-1 which exposes the underlying second stack of epitaxial semiconductor layers 810-2. The sacrificial dielectric material 820 is removed using any suitable etch process and etch chemistry that is configured to etch away the sacrificial dielectric material 820 selective to the materials of, e.g., the residual dielectric layer 141A, the underlying second stack of epitaxial semiconductor layers 810-2, and the MDI layer 125.

Next, FIG. 9D is a schematic cross-sectional side view of an intermediate structure of the semiconductor integrated circuit device 400 which is obtained after selectively etching away the sacrificial layers 121s, 122s, and 123s of the second stack of epitaxial semiconductor layers 810-2 to release the channel layers 121, 122, and 123 of the second transistor 120. It is to be noted that the channel layers 121, 122, and 123 of the second transistor 120 can be released using the same or similar processes as discussed above (e.g., in conjunction with FIG. 8E) for releasing the channel layers 111 and 112 of the first transistor 110, the details of which need not be repeated.

Next, FIG. 9E is a schematic cross-sectional side view of an intermediate structure of the semiconductor integrated circuit device 400 which is obtained after forming interfacial layers and high-k gate dielectric layers 143 on exposed surfaces of the channel layers 121, 122, and 123 of the second transistor 120. Moreover, as schematically illustrated in FIG. 9E, the process of forming the high-k gate dielectric layers 143 on the channel layers 121, 122, and 123 also results in the formation of the residual dielectric layer 143A on the exposed surfaces of residual dielectric layer 141A and the MDI layer 125.

It is to be noted that the interfacial layers and high-k gate dielectric layers 143 can be formed on the channel layers 121, 122, and 123 of the second transistor 120 using the same or similar processes as discussed above (e.g., in conjunction with FIG. 8F) for forming the interfacial layers and the high-k gate dielectric layers 141 on the channel layers 111 and 112 of the first transistor 110, the details of which need not be repeated. Again, as noted above, the types of materials that are used to form the interfacial layers and the high-k gate dielectric layers 143 on the channel layers 121, 122, and 123 for the second transistor 120 can be selected to optimize the device performance for the given device type (e.g., P-type) of the second transistor 120.

Next, FIG. 9F is a schematic cross-sectional side view of an intermediate structure of the semiconductor integrated circuit device 400 which is obtained after forming the second metal gate electrode 144 of the second transistor 120. As noted above, in some embodiments, the second metal gate electrode 144 comprises a layer of a second work function metal which encapsulates the channel layers 121, 122, and 123 of the second transistor 120, wherein the second metal gate electrode 144 can be formed entirely of the second work function metal. In some embodiments, the second work function metal layer for the second transistor 120 comprises one or more layers of work function metal that are selected to achieve desired electrical properties of the metal gate for the given device type of the second transistor 120. For example, in some embodiments where the second transistor 120 is a P-type MOSFET, the second work function metal layer is engineered to ensure that the channel layers 121, 122, and 123 of the second transistor 120 effectively operate as a P-doped channel. In some embodiments, the second work function metal layer is formed of TiN.

In other embodiments, as noted above, the second metal gate electrode 144 can be formed by sequentially performing multiple metal deposition processes to initially deposit one or more layers of work function metal to form the second work function metal layer which encapsulates the channel layers 121, 122, and 123 of the second transistor 120, and then deposit a low-resistance metallic material (e.g., tungsten, ruthenium, cobalt, copper, aluminum, etc.) on the second work function metal layer to fill a remaining portion of the trench opening 820-1 with metallic material to form the second metal gate electrode 144. A CMP process is then performed to remove the overburden material (e.g., gate dielectric material and metal gate electrode material), and planarize the upper surface of the device down to the pre-metallization dielectric layer 106, resulting in the intermediate device structure shown in FIG. 9F.

As shown in FIG. 9F, the first metal gate 440-1 and the second metal gate 440-2 are electrically isolated by the MDI layer 125, the residual dielectric layers 141A and 143A, and the dielectric isolation layer 450. In this regard, the first metal gate 440-1 and the second metal gate 440-2 and isolation structures collectively form the exemplary split gate architecture of the metal gate 440 of the stacked complementary transistor structure 408 shown in FIG. 4.

Next, FIG. 9G is a schematic cross-sectional side view of an intermediate structure of the semiconductor integrated circuit device 400 which is obtained after forming the deep via 460 (or gate via contact) in the dielectric isolation layer 450 to provide a gate contact to the underlying buried first metal gate electrode 442 of the first metal gate 440-1 of the first transistor 110. In some embodiments, the deep via 460 is formed as part of a MOL process module in which via contacts are also formed in the pre-metallization dielectric layer 106 to provide source/drain contacts to the source/drain elements of the first and second transistors 110 and 120. The deep via 460 is formed by a process which comprises forming a via hole in the dielectric isolation layer 450 down the buried first metal gate electrode 442, and filling the via hole with a metallic material such as tungsten or cobalt, etc., to form the deep via 460. In some embodiments, a thin diffusion barrier layer is first deposited to line the inner surface of the via hole, followed by the deposition of the via metal.

FIGS. 10A-10H schematically illustrate a method for fabricating a semiconductor integrated circuit device comprising a stacked complementary transistor structure, according to an embodiment of the disclosure. In particular, FIGS. 10A-10H schematically illustrate a method for fabricating the semiconductor integrated circuit device 500 of FIG. 5 which comprises a pair of stacked complementary transistor structures with a cross-coupled gate configuration, according to an exemplary embodiment of the disclosure. To begin, FIG. 10A is a schematic cross-sectional side view (Y-Z plane) of an intermediate structure of the semiconductor integrated circuit device 500 which comprises a first dummy gate 1000₁ and a second dummy gate 1000₂ that are to be replaced with the first metal gate 540₁ and the second metal gate 540₂, respectively, of the first stacked complementary transistor structure 508₁ and the second stacked complementary transistor structure 508₂, respectively, which are disposed adjacent to each other on the substrate 502. The first and second dummy gates 1000₁ and 1000₂ each comprise a respective conformal oxide layer 1002 and a respective dummy gate electrode layer 1004 which is formed of a sacrificial material such as polysilicon or amorphous silicon material. In addition, the gate structures shown in FIG. 10A further comprise respective gate capping layers 1006 (or hard mask layer) which is disposed on the respective dummy gate electrode layers 1004.

The intermediate structure of the semiconductor integrated circuit device 500 as shown in FIG. 10A further comprises a first patterned stack of epitaxial semiconductor layers 1010₁ and a second patterned stack of stack of epitaxial semiconductor layers 1010₂. The first and second patterned stack of epitaxial semiconductor layers 1010₁ and 1010₂ have stacked architectures that are structural duplicates but disposed adjacent to each other in a mirrored configuration. In particular, the first and second patterned stack of epitaxial semiconductor layers 10101 and 10102 each comprise a first stack of epitaxial semiconductor layers 1010-1, a second stack of epitaxial semiconductor layers 1010-2, and a middle dielectric isolation layer 525 disposed between the first and second stacks of epitaxial semiconductor layers 1010-1 and 1010-2. The first stack of epitaxial semiconductor layers 1010-1 comprises a stack of alternating epitaxial semiconductor channel and sacrificial layers, including the channel layers 511 and 512 (associated with the first (bottom) transistors 510₁ and 510₂), and sacrificial layers 511s, 512s, and 513s. Similarly, the second stack of epitaxial semiconductor layers 1010-2 comprises a stack of alternating epitaxial semiconductor channel and sacrificial layers, including the channel layers 521, 522, and 523 (associated with the second (upper) transistors 520₁ and 520₂), and sacrificial layers 521s, 522s, and 523s.

Next, FIG. 10B is a schematic cross-sectional side view of an intermediate structure of the semiconductor integrated circuit device 500 which is obtained after forming the second metal gate 542₂ of the second transistor 520₂ of the second stacked complementary transistor structure 508₂, within the second dummy gate 1000₂. In some embodiments, the second metal gate 542₂ of the second transistor 520₂ is fabricated using a process which comprises, e.g., (i) patterning the second dummy gate 1000₂ to form a trench opening which exposes the second stack of epitaxial semiconductor layers 1010-2 of the second patterned stack of epitaxial semiconductor layers 1010₂, (ii) etching away the sacrificial layers 521s, 522s, and 523s to release the channel layers 521, 522, and 523 of the second transistor 520₂, (iii) forming the interfacial layers and high-k gate dielectric layers 544 on the exposed surfaces of the channel layers 521, 522, and 523 of the second transistor 520₂, and (iv) forming the second metal gate electrode 548₂ which encapsulates the channel layers 521, 522, and 523 of the second transistor 520₂. The second metal gate 542₂ of the second transistor 520₂ can be fabricated using the same or similar materials and fabrication techniques as discussed above.

Next, FIG. 10C is a schematic cross-sectional side view of an intermediate structure of the semiconductor integrated circuit device 500 which is obtained after forming the first metal gate 541₂ of the first transistor 510₁ of the first stacked complementary transistor structure 508₁. In some embodiments, the first metal gate 541₁ of the first transistor 510₁ is fabricated using a process which comprises, e.g., (i) patterning the first dummy gate 1000₁ to form a trench opening which exposes the second stack of epitaxial semiconductor layers 1010-2 of the first patterned stack of epitaxial semiconductor layers 1010₁, (ii) filling the trench opening with a sacrificial dielectric material 1020 which covers the second stack of epitaxial semiconductor layers 1010-2 of the first patterned stack of epitaxial semiconductor layers 1010₁, (iii) removing a remaining portion of the first dummy gate 1000₁ to expose first stack of epitaxial semiconductor layers 1010-1 of the first patterned stack of epitaxial semiconductor layers 1010₁, (iv) etching away the sacrificial layers 511s, 512s, and 513s to release the channel layers 511 and 512 of the first transistor 510₁, (v) forming the interfacial layers and high-k gate dielectric layers 543 on the exposed surfaces of the channel layers 511 and 512 of the first transistor 510₁, (vi) forming the first (buried) metal gate electrode 546₁ which encapsulates the channel layers 511 and 512 of the first transistor 510₁, and (vii) forming the first dielectric isolation layer 550₁ which is disposed over the first metal gate 541₁ of the first transistor 510₁. The exemplary device structures shown in FIG. 5 can be fabricated using the same or similar materials and fabrication techniques as discussed above.

Next, FIG. 10D is a schematic cross-sectional side view of an intermediate structure of the semiconductor integrated circuit device 500 which is obtained after selectively etching away the sacrificial dielectric material 1020 to form a trench opening 1020-1 which exposes the second stack of epitaxial semiconductor layers 1010-2 of the first patterned stack of epitaxial semiconductor layers 1010₁, and after removing a remaining portion of the second dummy gate 10002 to form an open region 1020-2 which exposes the first stack of epitaxial semiconductor layers 1010-1 of the second patterned stack of epitaxial semiconductor layers 1010₂.

Next, FIG. 10E is a schematic cross-sectional side view of an intermediate structure of the semiconductor integrated circuit device 500 which is obtained after selectively etching away the sacrificial layers 521s, 522s, and 523s of the second stack of epitaxial semiconductor layers 1010-2 of the first patterned stack of epitaxial semiconductor layers 1010₁ to release the channel layers 521, 522, and 523 of the second transistor 520₁, and after selectively etching away the sacrificial layers 511s, 512s, and 513s of the first stack of epitaxial semiconductor layers 1010-1 of the second patterned stack of epitaxial semiconductor layers 1010₂ to release the channel layers 511 and 512 of the first transistor 510₂. With this exemplary process flow, in some embodiments, the channel layers of the first transistor 510₂ and the second transistor 520₂ can be released using the same etch process to selective etch away the sacrificial layers.

Next, FIG. 10F is a schematic cross-sectional side view of an intermediate structure of the semiconductor integrated circuit device 500 which is obtained after forming the interfacial layers and the high-k gate dielectric layers 545 on the exposed surfaces of the channel layers 511 and 512 of the first transistor 510₂ and on the exposed surfaces of the channel layers 521, 522, and 523 of the second transistor 520₁. Indeed, since the first transistor 510₂ and the second transistor 520₁ are of the same device type (e.g., P-type MOSFETS), the same materials are used to form the interfacial layers and the high-k gate dielectric layers 545 on the exposed surfaces of the channel layers 511, 512, 521, 522, and 523 of the first transistor 510₂ and the second transistor 520₁. The interfacial layers can be concurrently formed on the exposed surfaces of the channel layers 511, 512, 521, 522, and 523 of the first transistor 510₂ and the second transistor 520₁ using the same deposition process, and high-k gate dielectric layers 545 can be concurrently formed on the channel layers 511, 512, 521, 522, and 523 of the first transistor 510₂ and the second transistor 520₁ using the same deposition process module.

Next, FIG. 10G is a schematic cross-sectional side view of an intermediate structure of the semiconductor integrated circuit device 500 which is obtained after forming the first metal gate electrode 548₁ which encapsulates the channel layers 521, 522, and 523 of the second transistor 520₁, after forming the first (buried) metal gate electrode 546₂ which encapsulates the channel layers 511 and 512 of the first transistor 510₂, and after forming the second dielectric isolation layer 550₂ which is disposed over the first metal gate 541₂ of the first transistor 510₂, and which surrounds the second metal gate 542₂ of the second transistor 520₂. In some embodiments, the intermediate structure shown in FIG. 10G is fabricated using a process which comprises, e.g., (i) depositing one or more metal layers of work function metal (and possible low-resistance fill metal) to fill the trench openings 1020-1 and 1020-2 (FIG. 10F) with gate metal, (ii) performing CMP to remove the overburden gate metal and gate dielectric material and planarizing the surface of the device structure down to the pre-metallization dielectric layer 506 (thereby forming the second metal gate electrode 548₁ in the first gate region), (iii) performing a gate metal recess in the second gate region to form the first (buried) metal gate electrode 546₂, and (iv) forming the second dielectric isolation layer 550₂. With this process, since the first transistor 510₂ and the second transistor 520₁ are of the same device type (e.g., P-type MOSFETS), the same gate metal materials (e.g., work function metal) are used to form the second metal gate electrode 548₁ of the second transistor 520₁, and the first (buried) metal gate electrode 546₂ of the first transistor 510₂.

Next, FIG. 10H is a schematic cross-sectional side view of an intermediate structure of the semiconductor integrated circuit device 500 which is obtained after forming the first horizontal metallic strap element 570 on the front-side of the substrate 502, and after forming the second horizontal metallic strap element 572 on the back-side of the substrate 502. As noted above, the insulating plug 574 (as shown in FIG. 5) can be formed in the back-side of the substrate 502 by partially recessing the metal of the second horizontal metallic strap element 572, and then filling the recess with insulating material to form the insulating plug 574. Additional fabrication steps are then performed to form the first and second deep vias 560₁ and 560₂ in the first and second dielectric isolation layers 550₁ and 550₂, and to form the MOL layer comprising the ILD layer 580 and gate contacts 590, 592, 594, and 596, resulting in the device structure shown in FIG. 5.

It is to be understood that the exemplary methods discussed herein for fabricating stacked complementary transistor structures can be readily incorporated within semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit as disclosed herein can be employed in applications, hardware, and/or electronic systems. Suitable hardware and systems for implementing the exemplary embodiments described herein may include, but are not limited to, personal computers, communication networks, electronic commerce systems, portable communications devices (e.g., cell and smart phones), solid-state media storage devices, functional circuitry, etc. Systems and hardware incorporating such integrated circuits are considered part of the exemplary embodiments described herein. Given the teachings of the disclosure provided herein, one of ordinary skill in the art will be able to contemplate other implementations and applications of the exemplary techniques disclosed herein.

Moreover, the exemplary structures described above may be implemented in integrated circuits chips. The resulting integrated circuit chips can be distributed by a fabricator in raw wafer form (that is, as a single wafer that has multiple unpackaged chips), as a bare die, or in a packaged form. In the latter case, a chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a stacked transistor structure which comprises a first transistor of a first type, and a second transistor of a second type which is opposite the first type, and disposed over the first transistor; and
a shared gate structure which comprises:
a first metal gate structure of the first transistor;
a second metal gate structure of the second transistor, wherein the second metal gate structure is embedded in the first metal gate structure with a dielectric layer disposed between the first metal gate structure and the second metal gate structure; and
a metallic connection layer which electrically connects upper regions of the first metal gate structure and the second metal gate structure.

2. The device of claim 1, wherein the metallic connection layer comprises a metallic strap element that is disposed on an upper surface of the first metal gate structure and on an upper surface of the second metal gate structure.

3. The device of claim 1, wherein the metallic connection layer comprises a metallic plug element that is formed within an upper surface region of the first metal gate structure and within an upper surface region of the second metal gate structure.

4. The device of claim 1, wherein:
the first metal gate structure comprises a first gate dielectric layer, and a first work function metal layer which encapsulates at least one channel layer of the first transistor;
the second metal gate structure comprises a second gate dielectric layer, and a second work function metal layer which encapsulates at least one channel layer of the second transistor; and
the dielectric layer disposed between the first metal gate structure and the second metal gate structure comprises a first residual dielectric layer comprised of dielectric material of the first gate dielectric layer, and a second residual dielectric layer comprised of dielectric material of the second gate dielectric layer.

5. The device of claim 4, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of a same oxide material.

6. The device of claim 4, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of different oxide materials.

7. The device of claim 1, wherein:
the first transistor and the second transistor each comprise a gate-all-around nanosheet field-effect transistor; and
the first transistor is a P-type transistor and the second transistor is an N-type transistor, or the first transistor is an N-type transistor and the second transistor is a P-type transistor.

8. A device, comprising:
a stacked transistor structure which comprises a first transistor of a first type, and a second transistor of a second type which is opposite the first type, and disposed over the first transistor; and
a split gate structure which comprises a first metal gate structure of the first transistor, and a second metal gate structure of the second transistor, wherein the second metal gate structure is embedded in the first metal gate structure with a dielectric layer disposed between the first metal gate structure and the second metal gate structure.

9. The device of claim 8, wherein:
the first metal gate structure comprises a first gate dielectric layer, and a first work function metal layer which encapsulates at least one channel layer of the first transistor;
the second metal gate structure comprises a second gate dielectric layer, and a second work function metal layer which encapsulates at least one channel layer of the second transistor; and
the dielectric layer disposed between the first metal gate structure and the second metal gate structure comprises a first residual dielectric layer comprised of dielectric material of the first gate dielectric layer, and a second residual dielectric layer comprised of dielectric material of the second gate dielectric layer.

10. The device of claim 9, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of a same oxide material.

11. The device of claim 9, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of different oxide materials.

12. The device of claim 8, wherein:
the first transistor and the second transistor each comprise a gate-all-around nanosheet field-effect transistor; and
the first transistor is a P-type transistor and the second transistor is an N-type transistor, or the first transistor is an N-type transistor and the second transistor is a P-type transistor.

13. A device, comprising:
a stacked transistor structure which comprises a first transistor of a first type, and a second transistor of a second type which is opposite the first type, and disposed over the first transistor; and
a split gate structure which comprises a dielectric isolation layer, a first metal gate structure of the first transistor, and a second metal gate structure of the second transistor;
wherein the second metal gate structure is embedded in the dielectric isolation layer with a dielectric layer comprised of gate dielectric material disposed between the second metal gate structure and the dielectric isolation layer; and
wherein the first metal gate structure is disposed below the dielectric isolation layer.

14. The device of claim 13, wherein:
the first metal gate structure comprises a first gate dielectric layer, and a first work function metal layer which encapsulates at least one channel layer of the first transistor;
the second metal gate structure comprises a second gate dielectric layer, and a second work function metal layer which encapsulates at least one channel layer of the second transistor; and
the dielectric layer disposed between the second metal gate structure and the dielectric isolation layer comprises a first residual dielectric layer comprised of dielectric material of the first gate dielectric layer, and a second residual dielectric layer comprised of dielectric material of the second gate dielectric layer.

15. The device of claim 14, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of a same oxide material.

16. The device of claim 14, further comprising:
a first interfacial layer disposed on a surface of the at least one channel layer of the first transistor; and
a second interfacial layer disposed on a surface of the at least one channel layer of the second transistor;
wherein the first interfacial layer and the second interfacial layer are formed of different oxide materials.

17. The device of claim 13, further comprising a metallic via disposed in the dielectric isolation layer and in contact with the first metal gate structure.

18. The device of claim 13, wherein:
the first transistor and the second transistor each comprise a gate-all-around nanosheet field-effect transistor; and
the first transistor is a P-type transistor and the second transistor is an N-type transistor, or the first transistor is an N-type transistor and the second transistor is a P-type transistor.

19. A device, comprising:
a first stacked transistor structure and a second stacked transistor structure disposed on a substrate, wherein:
the first stacked transistor structure comprises a first transistor of a first type, a second transistor of a second type which is opposite the first type, and disposed over the first transistor, and a first split gate structure comprising a first metal gate structure of the first transistor, and a second metal gate structure of the second transistor, wherein the first metal gate structure and the second metal gate structure are isolated from each other;
the second stacked transistor structure comprises a third transistor of the second type, a fourth transistor of the first type and disposed over the third transistor, and a second split gate structure comprising a third metal gate structure of the third transistor, and a fourth metal gate structure of the fourth transistor, wherein the third metal gate structure and the fourth metal gate structure are isolated from each other; and
a first metallic connection element which connects the second metal gate structure and the fourth metal gate structure. 20 The device of claim 19, further comprising a second metallic connection element which connects first metal gate structure and the third metal gate structure.

21. The device of claim 19, wherein the first metal gate structure and the third metal gate structure are disposed in contact with each other.

22. The device of claim 19, wherein:
the first split gate structure comprises a first dielectric isolation layer;
the second metal gate structure of the second transistor is embedded in the first dielectric isolation layer;
the first metal gate structure of the first transistor is disposed below the first dielectric isolation layer;
the second split gate structure comprises a second dielectric isolation layer;
the fourth metal gate structure of the fourth transistor is embedded in the second dielectric isolation layer; and
the third metal gate structure of the third transistor is disposed below the second dielectric isolation layer.

23. A method, comprising:
forming a stacked transistor structure which comprises a first transistor of a first type, a second transistor of a second type, which is opposite the first type and disposed over the first transistor; and
forming a gate structure which comprises a first metal gate structure of the first transistor, and a second metal gate structure of the second transistor, wherein the second metal gate structure is embedded in the first metal gate structure with a dielectric layer disposed between the first metal gate structure and the second metal gate structure.

24. The method of claim 23, wherein forming the gate structure comprises forming a shared gate structure by forming a metallic connection layer to electrically connect upper regions of the first metal gate structure and the second metal gate structure.

25. The method of claim 23, wherein forming the gate structure comprises forming a split gate structure by recessing the first metal gate structure to a level which is below the second metal gate structure, and forming a dielectric isolation layer which is disposed above the recessed first metal gate structure and which surrounds the second metal gate structure.
